(19) United States
(12) Patent Application Publication
(10) Pub. No.: US 2002/0170827 A1
(43) Pub. Date: Nov. 21, 2002

(54) Multilayer substrate for a buildup with a via, and method for producing the same

(76) Inventor: Shuichi Furuya, Tokyo (JP)

Correspondence Address: KNOBBE MARTENS OLSON & BEAR LLP, 2040 MAIN STREET, FOURTEENTH FLOOR, IRVINE, CA, 92614, US

(21) Appl. No.: 10/090,420

(22) Filed: Feb. 27, 2002

(30) Foreign Application Priority Data
Feb. 28, 2001 (JP) 2001-55476
May 24, 2001 (JP) 2001-155501
Jan. 31, 2002 (JP) 2002-24817

(51) Int. Cl. C23C 14/32

(52) U.S. Cl. 205/131; 204/192.15

(57) ABSTRACT

A multilayer substrate for a buildup with a via, which multilayer substrate comprises a base material comprising an insulation resin layer on which a predetermined hole is formed,

wherein an electrodeposition layer is formed by circular oscillation electroplating on the inside wall surface of the hole and on the predetermined surface of the insulation resin layer,

the electrodeposition layer on the inside wall surface of the hole being formed in a thickness greater than the electrodeposition layer formed on the surface of the insulation resin layer and a method for the production of the substrate.

### FIELD

The present invention relates to a multilayer substrate for a buildup with a via and to a method for producing the substrate, and, particularly, to a multilayer substrate for a buildup with a via, which substrate is provided with an electrodeposition layer formed by circular oscillation electroplating and to a method for producing the substrate.

### BACKGROUND

In recent years, a substrate for a buildup has been adopted as a circuit substrate to keep up with the developments of high quality and small-sized electronic devices such as portable telephones, portable type personal computers and PDAs.

In one example of conventional substrates for a buildup, as shown in FIG. 21(a) and FIG. 21(b), a bump (222) is formed on one side of a copper foil (221) by printing. The copper foil (221) on which the bump (222) is formed, an epoxy resin layer (223) containing glass fiber and a copper foil (224) are press-molded under heating to laminate the copper foil (221), the resin layer (223) and the copper foil (224), thereby building up interlayer electrical connection. Also, as shown in FIG. 22(a) to FIG. 22(c), another example of a conventional substrate for a buildup has a structure in which a hole (231) is opened in a resin layer (230), a conductive paste (232) is filled in the hole (231) and then a copper layer (copper foil) (233) is formed (laminated) to build up interlayer electrical connection.

Also, as shown in FIG. 23(a) to FIG. 23(c), in still another example, a hole (242) is opened in a laminate plate consisting of a copper foil (240) and a resin layer (241) and copper plating is carried out to build up interlayer electrical connection. In these figures, 245 represents an electrodeposition layer formed by copper plating.

In the substrates for a buildup shown in FIG. 21 and FIG. 22 in the prior art, the structure in which the hole diameter is 100 μm, the ratio of the circuit width to the interval (L/S) is 75/75 μm, the thickness of the resin layer is 100 μm and the thickness of copper is 18 to 35 μm is said to be their limit. A further micro-sized substrate for a buildup is needed to keep up with the development of high quality and small-sized electronic devices.

As refining technologies, the technologies are used, wherein, as shown in FIG. 23, a hole is opened in the resin layer by using a laser method and the copper layer is formed by plating to build up interlayer electrical connection. These technologies, however, involve limitation in refining techniques, for example, the structure in which the hole diameter is 75 μm, L/S is 45/45 μm, the thickness of the insulated resin layer is 60 μm and the thickness of copper is 18 μm is their limit. A more micro-sized structure causes a sharp increase in price, giving rise to a cost problem.

An electrodeposition layer as shown in FIG. 24 is formed especially by electroplating of the inside wall surface of such a conventional fine hole. Specifically, an electrodeposition layer (245a) on the surface of a resin layer (241) becomes thick, an electrodeposition layer (245b) on the inside wall surface of the hole becomes thin and also a thin-electrodeposition layer portion (245d) occurs at the end of the bottom of the hole between the electrodeposition layer formed on the inside wall surface and an electrodeposition layer (245c) formed on copper layer (240) of the bottom, posing the problem that interlayer electrical connection is impaired.

Also, a conventional multilayer substrate in which a copper layer is formed on a resin layer by plating has such the problems that the peeling strength (strength required to peel off the copper layer from the resin layer) of the copper layer is low, that the peeling strength required on the parts-packaged side of the multilayer substrate can not be satisfied, and that the copper layer is peeled off from the resin layer when packaging the parts.

### SUMMARY

The present invention is a multilayer substrate for a buildup with a via, which multimlayer substrate comprises a base material comprising an insulation resin layer and, if necessary, a copper layer or an extra thin copper foil formed on either one or both surfaces of the insulation resin layer, and which multilayer substrate has a predetermined hole formed on the insulation resin layer,

wherein an electrodeposition layer is formed by circular oscillation electroplating on the inside wall surface of the hole and on the predetermined surface of the insulation resin layer, the electrodeposition layer on the inside wall surface of the hole being formed more thickly than the electrodeposition layer formed on the surface of the insulation resin layer.

Also, the present invention is a method for producing a multilayer substrate for a buildup with a via, comprising:

a step of forming a predetermined hole using a laser on a base material comprising an insulation resin layer and, if necessary, a copper layer or an extra thin copper foil formed on either one or both surfaces of the insulation resin layer;

a step of performing electroless plating, copper sputtering or activating treatment on the base material on which the hole is formed; and

an electroplating step of performing electroplating to generate a vortex flow of an electroplating solution inside the hole by oscillating the base material circularly in an electroplating bath, to form an electrodeposition layer on the inside wall surface of the hole and on a predetermined surface of the insulation resin layer,

whereby the electrodeposition layer on the inside wall surface of the hole is formed more thickly than the electrodeposition layer formed on the surface of the insulation resin layer.

Other and further objects, features, and advantages of the invention will appear more fully from the following description, taken in connection with the accompanying drawings.

### BRIEF DESCRIPTION OF THE DRAWINGS

FIG. 1(a), FIG. 1(b) and FIG. 1(c) are explanatory views showing the formation of a hole and a circular oscillation electroplating step in Example 1 according to the present invention.

FIG. 2 is a partly enlarged sectional view of a multilayer substrate for a buildup with a via which is obtained in Example 1 according to the present invention.

FIG. 3 is a partly sectional view of a multilayer substrate for a buildup with a via which is obtained in Example 1 according to the present invention.

FIG. 4 is a plan view showing one example of the multilayer substrate for a buildup with a via of the present invention.

FIG. 5 is a plan view showing another example of the multilayer substrate for a buildup with a via of the present invention.

FIG. 6(a), FIG. 6(b) and FIG. 6(c) are sectional views showing a step of forming a hole and the obtained multilayer substrate for a buildup with a via in Example 2 according to the present invention.

FIG. 7(a), FIG. 7(b) and FIG. 7(c) are explanatory views showing the formation of a through-hole and a circular oscillation electroplating step in Example 3 according to the present invention.

FIG. 8(a) and FIG. 8(b) are partly enlarged sectional views of a multilayer substrate for a buildup with a via which is obtained in Example 3 according to the present invention.

FIG. 9(a), FIG. 9(b) and FIG. 9(c) are sectional views showing a step of forming a through-hole and the obtained multilayer substrate for a buildup with a via in Example 4 according to the present invention.

FIG. 10(a), FIG. 10(b) and FIG. 10(c) are sectional views showing a step of forming a through-hole and the obtained multilayer substrate for a buildup with a via in Example 5 according to the present invention.

FIG. 11(a), FIG. 11(b) and FIG. 11(c) are sectional views showing a step of forming a through-hole and a resist and the obtained multilayer substrate for a buildup with a via which has a copper circuit in Example 6 according to the present invention.

FIG. 12(a), FIG. 12(b), FIG. 12(c) and FIG. 12(d) are sectional views showing a step of forming a through-hole in Example 7 according to the present invention.

FIG. 13(e) and FIG. 13(f) are explanatory views showing a circular oscillation electroplating step and the obtained multilayer substrate for a buildup with a via in Example 7 according to the present invention.

FIG. 14 is a partly enlarged sectional view showing a multilayer substrate for a buildup with a via which is obtained in Example 7 according to the present invention.

FIG. 15(a), FIG. 15(b), FIG. 15(c) and FIG. 15(d) are explanatory views showing the formation of a through-hole, a circular oscillation electroplating step and the obtained multilayer substrate for a buildup with a via in Example 8 according to the present invention.

FIG. 16 is a partly enlarged sectional view showing a multilayer substrate for a buildup with a via which is obtained in Example 8 according to the present invention.

FIG. 17(a), FIG. 17(b), FIG. 17(c), FIG. 17(d) and FIG. 17(e) are explanatory views showing the formation of a through-hole, a circular oscillation electroplating step and the obtained multilayer substrate for a buildup with a via in Example 9 according to the present invention.

FIG. 18(a), FIG. 18(b), FIG. 18(c), FIG. 18(d) and FIG. 18(e) are explanatory views showing the formation of a hole, a circular oscillation electroplating step and the obtained multilayer substrate for a buildup with a via in Example 10 according to the present invention.

FIG. 19 is a partly enlarged sectional view showing a multilayer substrate for a buildup with a via which is obtained in Example 11 according to the present invention.

FIG. 20(a), FIG. 20(b) and FIG. 20(c) are explanatory views showing a step of forming a hole in Example 12 according to the present invention.

FIG. 21(a) and FIG. 21(b) are sectional views showing one example of a conventional substrate for a buildup.

FIG. 22(a), FIG. 22(b) and FIG. 22(c) are sectional views showing another example of a conventional substrate for a buildup.

FIG. 23(a), FIG. 23(b) and FIG. 23(c) are sectional views showing still another example of a conventional substrate for a buildup.

FIG. 24 is a sectional view showing an electrodeposition layer on the inside surface of a hole in a conventional substrate for a buildup.

### DETAILED DESCRIPTION

According to the present invention, the following measures are provided:

(1) A multilayer substrate for a buildup with a via, which multilayer substrate comprises a base material comprising an insulation resin layer and, if necessary, a copper layer or an extra thin copper foil formed on either one or both surfaces of said insulation resin layer, and which multilayer substrate has a predetermined hole formed on said insulation resin layer,

wherein an electrodeposition layer is formed by circular oscillation electroplating on the inside wall surface of said hole and on the predetermined surface of said insulation resin layer,

the electrodeposition layer on said inside wall surface of said hole being formed in a thickness greater than the electrodeposition layer formed on said surface of said insulation resin layer;

(2) The multilayer substrate for a buildup with a via according to (1), which multilayer substrate comprises the base material comprising the insulation resin layer and the copper layer formed on one surface thereof, and which multilayer substrate has the hole which reaches said copper layer formed on one surface and is formed on the insulation resin layer,

wherein the electrodeposition layer is formed by circular oscillation electroplating on the inside wall surface of said hole and on the surface of the copper-layer unformed-side of said insulation resin layer, the electrodeposition layer on said inside wall surface of said hole being formed in a thickness greater than the electrodeposition layer formed on said surface of said insulation resin layer;

(3) The multilayer substrate for a buildup with a via according to (1), which multilayer substrate comprises the base material on which the hole penetrating through the insulation resin layer is formed,

wherein the electrodeposition layer is formed by circular oscillation electroplating on the inside wall surface of said hole and on both surfaces of said insulation resin layer,

the electrodeposition layer on said inside wall surface of said hole being formed in a thickness greater than the electrodeposition layer formed on both surfaces of said insulation resin layer;

(4) The multilayer substrate for a buildup with a via according to (2) or (3), wherein the hole on the insulation resin layer is filled up with the electrodeposition layer formed on inside wall surface of said hole on the insulation resin layer;

(5) The multilayer substrate for a buildup with a via according to (2) to (4), wherein the hole provided with the electrodeposition layer formed on the inside wall surface thereof in the insulation resin layer is plurally formed at predetermined intervals on the multilayer substrate;

(6) The multilayer substrate for a buildup with a via according to (2) to (4), wherein the hole provided with the electrodeposition layer formed on the inside wall surface thereof in the insulation resin layer is plurally formed at circuit-formed positions on the multilayer substrate;

(7) A method for producing a multilayer substrate for a buildup with a via, comprising:

a step of forming a predetermined hole using a laser in a base material comprising an insulation resin layer and, if necessary, a copper layer or an extra thin copper foil formed on either one or both surfaces of said insulation resin layer;

a step of performing electroless plating, copper sputtering or activating treatment on the base material on which said hole is formed; and

an electroplating step of performing electroplating to generate a vortex flow of an electroplating solution inside said hole by oscillating said base material circularly in an electroplating bath, to form an electrodeposition layer on the inside wall surface of said hole and on a predetermined surface of said insulation resin layer, whereby the electrodeposition layer on the inside wall surface of said hole is formed in a thickness larger than the electrodeposition layer formed on said surface of said insulation resin layer;

(8) The method for producing the multilayer substrate for a buildup with a via according to (7), comprising:

a step of forming the hole reaching the copper layer, formed on one surface, by using a laser on the insulation resin layer formed on the base material comprising said insulation resin layer and said copper layer formed on one surface;

a step of performing electroless plating, copper sputtering or activating treatment on the base material in which said hole is formed; and

an electroplating step of performing electroplating to generate the vortex flow of the electroplating solution inside of said hole by oscillating said base material circularly in the electroplating bath to form the electrodeposition layer on the inside wall surface of said hole and on the surface of the copper-layer unformed-side of said insulation resin layer, whereby the electrodeposition layer on said inside wall surface of said hole is formed in a thickness larger than the electrodeposition layer formed on said surface of the copper-layer unformed-side of said insulation resin layer;

(9) The method for producing the multilayer substrate for a buildup with a via according to (7), comprising:

a step of forming a hole penetrating through an insulation resin layer by using a laser;

a step of performing electroless plating, copper sputtering or activating treatment on the base material in which said hole is formed; and

an electroplating step of performing electroplating to generate the vortex flow of an electroplating solution inside said hole by oscillating the base material circularly in the electroplating bath, to form the electrodeposition layer on the inside wall surface of said hole and on both surfaces of said insulation resin layer, whereby the electrodeposition layer on the inside wall surface of the said is formed in a thickness larger than the electrodeposition layer formed on both surfaces of said insulation resin layer;

(10) The method for producing the multilayer substrate for a buildup with a via according to (8) or (9), wherein, in the electroplating step of generating the vortex flow inside the hole by oscillating circularly in the electroplating bath, the flow rate of the electroplating solution inside said hole is higher than that of the electroplating solution on the surface of the insulation resin layer;

(herein, the multilayer substrates for a buildup with a via according to the above (1) to (6) and the methods for producing a multilayer substrate for a buildup with a via according to the above (7) to (10) are collectively referred to as the first embodiment of the present invention);

(11) The multilayer substrate for a buildup with a via according to (1), which multilayer substrate comprises a base material having an extra thin copper foil on one side of the insulation resin layer and a through-hole formed thereon,

wherein the electrodeposition layer is formed on the surface of said extra thin copper foil, on the surface of said insulation resin layer and on the inside wall surface of said through-hole by circular oscillation electroplating,

the electrodeposition layer on the inside wall surface of the through-hole being formed in a thickness larger than the electrodeposition layer on the surface of the insulation resin layer;

(12) The multilayer substrate for a buildup with a via according to (11), wherein the through-hole is filled up with the electrodeposition layer formed on the inside wall surface of said through-hole;

(13) The multilayer substrate for a buildup with a via according to (1), which multilayer substrate comprises the base material having an extra thin copper foil on one surface of the insulation resin layer and which multilayer substrate has a hole reaching said extra thin copper foil and formed on the insulation resin layer,

wherein the electrodeposition layer is formed on the surface of the extra thin copper foil, on the surface of said insulation resin layer and on the inside wall surface of said hole by circular oscillation electroplating, the electrodeposition layer on said inside wall surface of said hole being formed in a thickness larger than the electrodeposition layer on the surface of said insulation resin layer;

(14) The multilayer substrate for a buildup with a via according to (13), wherein the hole is filled up with the electrodeposition layer formed on the inside wall surface of the hole reaching the extra thin copper foil in the insulation resin layer;

(15) The multilayer substrate for a buildup with a via according to (11) to (14), wherein the extra thin copper foil on one surface of the insulation resin layer has a thickness of 1 to 5 μm;

(16) The method of producing the multilayer substrate for a buildup with a via according to (7), comprising:

a step of working an extra thin copper foil of the base material having said extra thin copper foil on one surface of the insulation resin layer by treatment allowing good laser workability to form a through-hole from the side of said extra thin copper foil by laser via-working;

a step of performing electroless plating, copper sputtering or activating treatment on the base material on which the through-hole is formed; and

a circular oscillation electroplating step of performing electroplating to generate the vortex flow of the electroplating solution inside said through-hole by oscillating said base material circularly in the electroplating bath to thereby form the electrodeposition layer on the surface of the extra thin copper foil, on the surface of the insulation resin layer and on the inside wall surface of the through-hole in said base material, wherein the electrodeposition layer on said inside wall surface of said through-hole is formed in a thickness larger than the electrodeposition layer formed on said surface of said insulation resin layer (preferably, the method for producing a multilayer substrate for a buildup with a via according to (11) or (12));

(17) The method for producing a multilayer substrate for a buildup with a via according to (7), comprising:

a step of peeling off the base material from a carrier copper foil and forming a through-hole by laser via-working from the side of the extra thin copper foil treated for allowing good laser workability, wherein the base material having the extra thin copper foil treated for allowing good laser workability on one surface of the insulation resin layer is bonded with the carrier copper foil on said extra thin copper foil;

a step of performing electroless plating, copper sputtering or activating treatment on said base material on which the through-hole is formed; and

a circular oscillation electroplating step of performing electroplating to generate the vortex flow of the electroplating solution inside of the through-hole by oscillating said base material circularly in the electroplating bath to thereby form the electrodeposition layer on the surface of the extra thin copper foil, on the surface of the insulation resin layer and on the inside wall surface of the through-hole on said base material, wherein the electrodeposition layer on said inside wall surface of said through-hole is formed in a thickness larger than the electrodeposition layer formed on the surface of said insulation resin layer (preferably, the method for producing a multilayer substrate for a buildup with a via according to (11) or (12));

(18) The method for producing the multilayer substrate for a buildup with a via according to (7), comprising:

a step of processing a copper foil of the base material having said copper foil on one surface of the insulation resin layer by treatment for allowing good laser workability and forming a through-hole from the side of said copper foil by laser via-working;

a step of making the copper foil of said base material, on which said through-hole is formed, into an extra thin copper foil by etching;

a step of performing electroless plating, copper sputtering or activating treatment on said base material; and

a circular oscillation electroplating step of performing electroplating to generate the vortex flow of the electroplating solution inside the through-hole by oscillating said base material circularly in an electroplating bath to thereby form the electrodeposition layer on the surface of the extra thin copper foil, on the surface of the insulation resin layer and on the inside wall surface of said through-hole in said base material, wherein the electrodeposition layer on said inside wall surface of said through-hole is formed in a thickness larger than the electrodeposition layer formed on said surface of the insulation resin layer (preferably, the method for producing a multilayer substrate for a buildup with a via according to (11) or (12));

(19) The method for producing the multilayer substrate for a buildup with a via according to (7), comprising:

a step of forming the hole reaching the extra thin copper foil on the insulation resin layer by performing laser via-working from the side of the insulation resin layer of the base material having the extra thin copper foil on one surface of the insulation resin layer;

a step of performing electroless plating, copper sputtering or activating treatment on said base material on which said hole reaching said extra thin copper foil is formed on said insulation resin layer; and

a circular oscillation electroplating step of performing electroplating to generate the vortex flow of the electroplating solution inside said hole of said insulation resin layer reaching said extra thin copper foil by oscillating said base material circularly in the electroplating bath to thereby form the electrodeposition layer on the surface of the extra thin copper foil, on the surface of the insulation resin layer and on the inside wall surface of the hole in the base material, wherein the electrodeposition layer on the inside wall surface of said hole is formed in a thickness larger than the electrodeposition layer formed on said surface of said insulation resin layer (preferably, the method for producing a multilayer substrate for a buildup with a via according to (13) or (14)); and

(20) The method for producing the multilayer substrate for a buildup with a via according to (7), comprising:

a step of forming the hole reaching the extra thin copper foil on the insulation resin layer by performing laser via-working from the side of the insulation resin layer of the base material in the condition that the base material is bonded with the carrier copper foil, wherein the base material provided with the extra thin copper foil on one surface of the insulation resin layer is bonded with a carrier copper foil;

a step of peeling off said base material provided with said hole reaching said extra thin copper foil which hole is formed on the insulation resin layer, from said carrier copper foil and performing electroless plating, copper sputtering or activating treatment on the base material in which the through-hole is formed; and

a circular oscillation electroplating step of performing electroplating to generate the vortex flow of the electroplating solution inside said hole of said insulation resin layer reaching said extra thin copper foil by oscillating said base material circularly in the electroplating bath to thereby form the electrodeposition layer on the surface of the extra thin copper foil, on the surface of said insulation resin layer and on said inside wall surface of said hole in the base material,

wherein the electrodeposition layer on said inside wall surface of said hole is formed in a thickness larger than the electrodeposition layer formed on the surface of said insulation resin layer (preferably, the method for producing a multilayer substrate for a buildup with a via according to (13) or (14))

(Herein, the multilayer substrates for a buildup with a via according to the above (1) and (11) to (15), and the method for producing a multilayer substrate for a buildup with a via according to the above (7) and (16) to (20) are collectively referred to as the second embodiment of the present invention).

Herein, the present invention means to include both the above first embodiment and second embodiment.

Herein, in the case in which the hole or through-hole formed in the insulation resin layer is not filled up with an electrodeposition layer, the term “the electrodeposition layer on the inside wall surface of the hole (or through-hole) is formed more thickly than the electrodeposition layer formed on the surface of the insulation resin layer” implies that no particular limitation is imposed on these thicknesses insofar as the electrodeposition layer on the inside wall surface of the hole or through-hole is formed in a thickness larger than the electrodeposition layer formed on the surface of the insulation resin layer. The thickness of the electrodeposition layer on the inside wall surface of the hole or through-hole is preferably one time or more and twice or less and more preferably 1.2 to 1.3 times that of the electrodeposition layer formed on the surface of the insulation resin layer.

Also, in the case in which the hole or through-hole formed in the insulation resin layer is filled up with an electrodeposition layer, the term “the electrodeposition layer on the inside wall surface of the hole (or through-hole) is formed more thickly than the electrodeposition layer formed on the surface of the insulation resin layer” means that the diameter of the hole or through-hole filled up with an electrodeposition layer is greater than the thickness of the electrodeposition layer formed on the inside wall surface.

In the multilayer substrate for a buildup with a via according to the first embodiment of the present invention, an electrodeposition may be formed by circular oscillation electroplating on a base material comprising a copper layer formed on one surface and an insulation resin layer on which a hole which reaches the copper layer formed on one surface. As a result, the electrodeposition layer formed on the inside wall surface of the hole in the insulation resin layer and on the surface of the insulation resin layer does not become thin at the end portion of the bottom of the hole reaching the copper layer formed on one surface and the electrodeposition layer on the inside wall surface of the hole is formed in a thickness greater than the electrodeposition layer formed on the surface of the insulation resin layer provided with no copper layer. Therefore, the interlayer electrical connection in the fine hole is highly reliable and also electroplating of the fine hole can be carried out at a high rate with ease.

Also, in the multilayer substrate for a buildup with a via according to the first embodiment of the present invention, an electrodeposition layer may be formed by circular oscillation electroplating on the base material on which the hole penetrating through the insulation resin layer is formed, thereby forming the electrodeposition layer on the inside wall surface of the through-hole in a thickness larger than the electrodeposition layer formed on both surfaces of the insulation resin layer. Also, because electrodeposition layers having almost the same thicknesses can be formed on both surfaces of the insulation resin layer, namely, on the upper surface and lower surface of the insulation resin layer respectively by circular oscillation electroplating, the substrate is not caused to be warped by plating stress of the electrodeposition layer. Moreover, since the electrodeposition layer is formed by circular oscillation electroplating on the upper surface and lower surface of the insulation resin layer, an electrodeposition layer as thin as 10 μm or less can be formed.

In the multilayer substrate for a buildup with a via according to the second embodiment of the present invention, a through-hole may be formed on a base material having an extra thin copper foil on one surface of an insulation resin layer and an electrodeposition layer may be formed by circular oscillation electroplating on the surface of the extra thin copper foil, on the surface of the insulation resin layer and on the inside wall surface of the through-hole, so that the peeling strength of the extra thin copper foil formed on one surface of the insulation resin layer from the insulation resin layer is heightened to a strength level which stands against the packaging of parts. In the conventional multilayer substrate in which a copper foil is formed on a resin layer by plating, the peeling strength of the copper layer is as low as about 0.7 kg/cm. However, in a multilayer substrate of the present invention in which a copper foil is formed on one surface of an insulation resin layer and an electrodeposition layer is formed on the surface of the copper foil by circular oscillation electroplating, the peeling strength of the part-packaged side on one surface can be made 0.9 kg/cm or more which is a strength enough to stand against the packaging of parts. Also, on the substrate in which the copper foil is formed on one surface of the insulation resin layer and a through-hole is formed, an electrodeposition layer may be formed by circular oscillation electroplating on the surface of the copper foil, on the surface of the insulation resin layer and on the inside wall surface of the through-hole. Because the electrodeposition layer formed on the inside wall surface of the through-hole is formed in a thickness greater than the electrodeposition layer formed on the surface of the insulation resin layer on which surface the copper foil of the base material is not formed, the interlayer electrical connection in the fine through-hole can be made highly reliable.

Also, the multilayer substrate for a buildup with a via according to the second embodiment of the present invention comprises a base material in which an extra thin copper foil is formed on one surface of an insulation resin layer and a hole reaching the extra thin copper foil is formed in the insulation resin layer, wherein an electrodeposition layer is formed by circular oscillation electroplating on the surface of the extra thin copper foil, on the surface of the insulation resin layer and on the inside wall surface of the through-hole. Therefore, the peeling strength of the extra thin copper foil formed on one surface of the insulation resin layer from the insulation resin layer is heightened to a strength level which stands against the packaging of parts. Also, because the electrodeposition layer formed on the inside wall surface of the hole reaching the extra thin copper foil formed on the insulation resin layer is formed in a thickness greater than the electrodeposition layer formed on the surface of the insulation resin layer, the interlayer electrical connection can be highly reliable.

First, the first embodiment of the present invention will be explained.

The multilayer substrate for a buildup with a via according to the first embodiment of the present invention and preferably a two-layer substrate for a buildup with a via comprises the copper layer and the insulation resin layer. Examples of materials used for the resin layer include FR4 Grade epoxy type resins, FR5 Grade heat-resistant resins, polyimides and glass cloth-containing resins (e.g., glass cloth-containing epoxy resins). The substrate is produced by laminating a copper foil on the resin material by using a press.

Also, as to the hole on the insulation resin layer, a fine hole reaching the copper layer is formed by laser working (laser machining).

Also, as pretreatment prior to circular oscillation electroplating, the base material on which the hole is formed may be performed by desmearing (surface-roughing), electroless plating and activating treatment for activating the surface of the insulation resin layer and the surface of the inside wall surface of the hole. As this pretreatment, the above-mentioned substrate on which the hole is formed may also be performed by copper sputtering. These pretreatments may be carried out in combination of two or more.

The electroplating is performed by oscillating the multilayer substrate circularly in a copper plating bath, wherein the hole is also oscillated circularly to generate a vortex flow of the plating solution inside the hole. The generation of a vortex flow of the plating solution ensures that the flow rate of the copper plating solution on the inside wall surface of the hole is higher than the flow rate of the plating solution on the surface of the insulation resin layer and a copper ion diffusion layer (zone having a low copper ion concentration) in the very vicinity of the inside wall surface of the hole is made thin. Because the electrodeposition rate is dependent on this diffusion layer with a low copper ion concentration, the electrodeposition rate (electrodeposition current) can be increased by making this diffusion layer thin and the increased electrodeposition rate leads to the result that the electrodeposition layer on the inside wall surface of the hole can be formed in a thickness greater than the electrodeposition layer formed on the surface of the insulation resin layer.

Also, the first embodiment of the present invention ensures that high-speed and highly-reliable plating can be performed with ease in even a hole such as those which have a hole diameter of 50 μm or less when the thickness of the multilayer substrate is 100 μm or less and are smaller than those currently in use.

Also, in the multilayer substrate for a buildup with a via comprising the base material on which the hole penetrating through the insulation resin layer is formed and which is provided with an electrodeposition layer formed by circular oscillation electroplating on the inside wall surface of the through-hole and on both surfaces of the insulation resin layer according to the first embodiment of the present invention, a resin material such as FR4 Grade epoxy resins, FR5 Grade heat-resistant resins, polyimides and glass cloth-containing resins (e.g., glass cloth-containing epoxy resins) can be used as the insulation resin layer and also, the through-hole on the insulation resin layer is prepared by forming a fine hole by laser working.

Also, as pretreatment prior to circular oscillation electroplating, the base material on which the through-hole is formed is performed by desmearing (surface-roughing), electroless plating and activating treatment for activating the surface of the insulation resin layer and the inside wall surface of the through-hole. As this pretreatment, the above-mentioned base material on which the through-hole is formed may also be performed by copper sputtering. These pretreatments may be carried out in combination of two or more.

The circular oscillation electroplating may be performed by oscillating the base material, on which the through-hole is formed in the insulation resin layer, circularly in a copper plating bath, wherein the through-hole may be also oscillated circularly to generate a vortex flow of the plating solution inside the through-hole. The generation of a vortex flow of the plating solution ensures that the flow rate of the copper plating solution on the inside wall surface of the through-hole is higher than the flow rate of the plating solution on both surfaces of the insulation resin layer and a copper ion diffusion layer (zone having a low copper ion concentration) in the very vicinity of the inside wall surface of the hole may be made thin. Because the electrodeposition rate is dependent on this diffusion layer with a low copper ion concentration, the electrodeposition rate (electrodeposition current) can be increased by making this diffusion layer thin and the increased electrodeposition rate (electrodeposition current) may lead to the result that the copper plating layer on the inside wall surface of the through-hole is formed in a thickness greater than the copper plating layer formed on the upper surface and lower surface of the insulation resin layer. Specifically, electrodeposition layers having a thickness of 10 μm or less can be formed as the copper plating layers formed on the upper surface and lower surface of the insulation resin layer. Also, the formation of the electrodeposition layers having the same thickness allows the substrate to be free from warpage caused by plating stress.

As mentioned above, the multilayer substrate in the first embodiment of the present invention may be provided with a hole, smaller than those currently in use, such as those having a depth of 100 μm or less and a hole diameter of 50 μm. Therefore, this multilayer substrate may be used for circuit substrates of devices such as cellular phones of next generations, portable type personal computers and PDAs and can keep up with the developments of high quality and small-sized devices.

Next, the second embodiment of the present invention will be explained.

In the second embodiment of the present invention, the base material is provided with the extra thin copper foil on one surface of the insulation resin layer. As the insulation resin layer, for example, an FR4 Grade epoxy type resin, FR5 Grade heat-resistant resin or polyimide can be used. The extra thin copper foil is laminated on one surface of the insulation resin layer by using a press. Alternatively, a glass cloth-containing resin (e.g., a glass cloth-containing epoxy resin) can be used as the insulation resin layer. If the glass cloth-containing resin is used, the deformation of the base material such as flexure or the occurrences of partial irregularities can be suppressed at the step of forming the hole by laser via-working.

Also, a copper foil may be laminated on one surface of the insulation resin layer by using a press and the copper foil may be thinned by etching to make a base material having an extra thin copper foil on one surface of the insulation resin layer.

It is preferable to carry out the step of thinning the copper foil into an extra thin copper foil by etching after the hole is formed by laser via-working. This is because there is the case where scattered substances produced in laser via-working are stuck to the copper foil and it is therefore preferable to thin the copper foil into an extra thin copper foil by etching after the hole is formed by laser via-working in order to remove the scattered substances and the like stuck in this thinning step.

As the extra thin copper foil to be formed on one surface of the insulation resin layer of the base material, those having a thickness of 1 to 5 μm are used. The peeling strength of the above-mentioned one surface can be increased to 0.9 kg/cm or more which is a strength enough to stand against the packaging of parts by using such an extra thin copper foil and by carrying out circular oscillation electroplating. Also, after the through-hole is formed by laser via-working in the base material provided with the extra thin copper foil having a thickness of 3 to 5 μm on one surface of the insulation resin layer, the thickness of the extra thin copper foil is decreased to 1 to 3 μm by etching and an electrodeposition layer is formed on the copper foil by circular oscillation electroplating, so that the thickness of the copper layer consisting of the electrodeposition layer and the extra thin copper foil having 1 to 3 μm can be reduced to 10 μm or less. This makes it possible to decrease a difference in thickness from the electrodeposition layer formed on the surface of the insulation resin layer.

Also, in the case of disposing a copper foil 12 μm in thickness on one surface of the insulation resin layer of the base material, the copper foil is preferably thinned into an extra thin copper foil 1 to 5 μm in thickness by etching after laser via-working.

Also, the copper foil is preferably made to have a low roughness, for instance, Rz=1.9 (μm) to 2.7 (μm), in respect to the roughness of the interface which is in contact with the insulation resin layer.

In order to form a through-hole from the copper foil side of the base material by laser via-working, the copper foil of the base material may be subjected to treatment allowing good laser workability. As the treatment allowing good laser workability, a Co-Cu alloy plating with a thickness of about 0.05 to 0.1 μm may be formed on the copper foil.

Also, the base material having the extra thin copper foil on one surface of the insulation resin layer is preferably bound with a carrier copper foil from the handling point of view. For example, as the carrier copper foil, one having a thickness of 35 μm may be used. The carrier copper foil is preferably provided with a peelable layer to peel off the base material easily from the carrier copper foil.

When the through-hole is formed from the copper foil side of the base material by laser via-working, the base material may be peeled off from the carrier copper foil to carry out laser via-working from the copper foil side which has been processed by treatment for allowing good laser workability. In the case of a base material provided with an extra thin copper foil as the copper foil on one surface of the insulation resin layer, it is preferable to remove the substances scattered by laser-via-working and stuck to the copper foil by lightly-etching.

Also, in the case where laser via-working is performed from the extra thin copper foil side the base material when a through-hole is formed on the base material, the energy required for opening the hole in the copper foil is about 5 to 10 times that required for opening a hole in the resin layer. If a laser is applied from the resin layer side, this gives a large damage to the resin layer. It is therefore preferable to apply a laser from the copper foil side to open a hole first and then to open a hole on the resin layer.

In the case of forming a hole reaching the extra thin copper foil on the insulation resin layer of the base material, it is preferable to carry out laser via-working from the side of the insulation resin layer in the condition that the base material is bound with the carrier copper foil. This is to prevent the extra thin copper foil from melting during laser via-working.

As the pretreatment for working the base material on which a through-hole is formed or the base material having a hole reaching the extra thin copper foil on the insulation resin layer by circular oscillation electroplating, the base material provided with the through-hole or the hole reaching the extra thin copper foil may be subjected to electroless plating, copper sputtering or activating treatment. Specifically, desmearing (surface-roughing), electroless plating, electroplating, copper sputtering or the like may be carried out. These pretreatments may be performed in combination of two or more.

The circular oscillation electroplating may be performed with circularly oscillating the base material provided with the through-hole or the base material provided with the hole reaching the extra thin copper foil in a copper plating bath. The base material is oscillated circularly, so that the hole of the base material is oscillated circularly, thereby generating a vortex flow of the plating solution inside the hole. The generation of the vortex flow of the plating solution causes the flow rate of the copper plating solution on the inside wall surface of the hole to be higher than each flow rate on the surface of the extra thin copper foil and the surface of the insulation resin layer, thereby making the copper ion diffusion layer (zone reduced in the concentration of copper ions) in the very vicinity of the inside wall surface of the hole thin. Because the electrodeposition rate is dependent on the diffusion layer reduced in the concentration of copper ions, the electrodeposition rate (electrodeposition current) can be increased by making the diffusion layer thin and the increased electrodeposition rate (electrodeposition current) brings about the result that the electrodeposition layer on the inside wall surface of the through-hole is formed in a thickness higher than the electrodeposition layer formed on the surface of the insulation resin layer provided with no copper foil.

The second embodiment of the present invention ensures that high speed and highly reliable plating can be performed with ease in even a hole such as those which have a hole diameter of 50 μm or less when the thickness of the multilayer substrate is 100 μm or less and are smaller than those currently in use.

Moreover, in the present invention, a circuit can be formed at the same time of the formation of the electrodeposition layer in the above-mentioned hole or through-hole (the hole or the through-hole may be filled up with the electrodeposition layer if necessary) by forming a resist for forming a desired circuit on the base material in advance before carrying out electroplating on the base material provided with a through-hole on the insulation resin layer or on the base material provided with a hole reaching the copper layer or extra thin copper foil formed on one surface of the insulation resin layer with circularly oscillating the base material in a copper plating solution and then by removing the resist after copper electroplating.

For instance, after the insulation resin layer using a glass cloth-containing epoxy resin as the base material may be subjected to working for opening a through-hole or a hole reaching the copper layer (or the extra thin copper foil) by a laser such as a CO₂ laser, pretreatment such as desmearing treatment or electroless plating may be performed and then a resist for forming a desired circuit may be formed on a desired position on both surfaces of the base material. The formation of the resist itself may be carried out using, for example, a dry film according to a usual method. After that, the entire surface of the substrate provided with the resist may be copper-plated with oscillating the base material circularly in a copper plating bath and then the resist may be removed. In this manner, the electrodeposition layer can be formed or filled in the via at the same time when a circuit is formed. Herein, as explained above, the electrodeposition layer on the inside wall surface of the hole or through-hole can be formed in a thickness higher than the electrodeposition layer formed on the surface of the insulation resin layer by carrying out copper plating with oscillating the base material circularly.

According to the present invention, the electrodeposition layer can be formed by circular oscillation electroplating on the substrate which comprises the insulation resin layer and the copper layer on one surface thereof and on which a hole reaching the copper layer is formed, thereby carrying out high speed and reliable plating with ease in a hole smaller than those currently in use and also the substrate has such an effect as highly reliable interlayer electrical connection in the micro-sized hole.

Also, according to the present invention, the electrodeposition layer may be formed by circular oscillation electroplating on the substrate on which a through-hole is formed on the insulation resin layer, thereby making the electrodeposition layer on both the upper surface and the lower surface of the insulation resin layer thinner than those provided with a copper foil layer on one surface. Also, since the electrodeposition layers having the same thicknesses are formed on both the upper surface and the lower surface, the substrate has such an effect as to be free from warpage caused by plating stress. Also, high speed and reliable plating can be carried out with ease in a hole smaller than those currently in use and also the substrate can produce such an effect as highly reliable interlayer electrical connection in the micro-sized hole.

Moreover, according to the present invention, a through-hole can be formed on the base material provided with the extra thin copper foil on one surface of the insulation resin layer and an electrodeposition layer can be formed by circular oscillation electroplating on the surface of the extra thin copper foil, on the surface of the insulation resin layer and on the inside wall surface of the through-hole and therefore the peeling strength between the insulation resin layer and the extra thin copper foil formed on one surface can be heightened to a strength enough to withstand against the packaging of parts and the substrate can show such an effect as highly reliable interlayer electrical connection in the micro-sized through-hole.

Also, the multilayer substrate of the present invention may be provided with the base material on which a hole reaching the extra thin copper foil may be formed on the insulation resin layer and an electrodeposition layer may be formed by circular oscillation electroplating on the surface of the extra thin copper foil, on the surface of the insulation resin layer and on the inside wall surface of the through-hole. Therefore the peeling strength between the insulation resin layer and the extra thin copper foil on one surface may be heightened to a strength enough to withstand against the packaging of parts and the substrate can show such an effect as highly reliable interlayer electrical connection.

The present invention will be hereinafter explained in more detail by way of examples as illustrated in the drawings. However, these examples are not intended to be limiting of the present invention.

### EXAMPLES

### Example 1

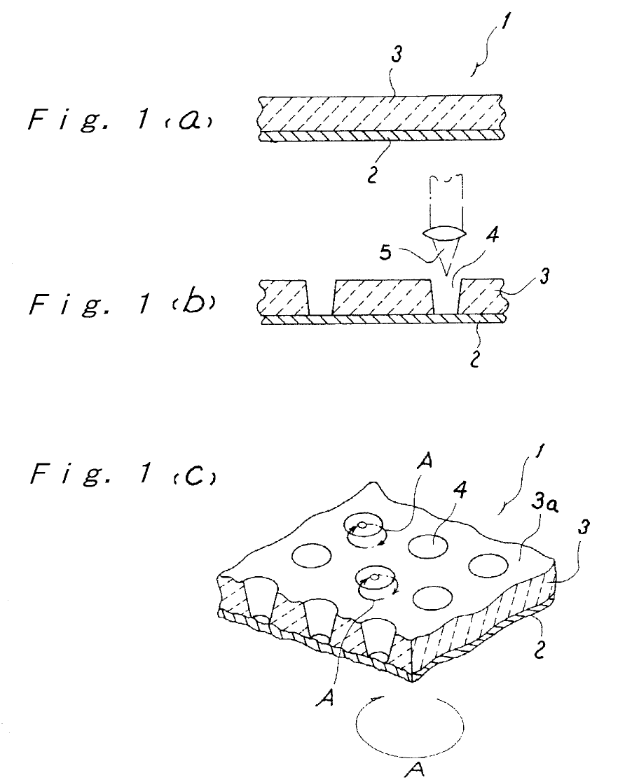

Example 1 according to the present invention will be explained with reference to FIG. 1 to FIG. 5.

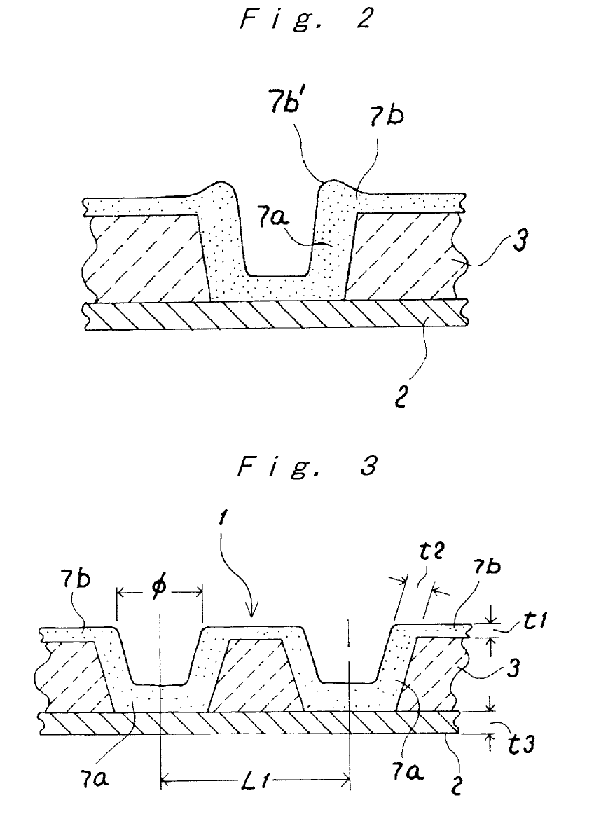

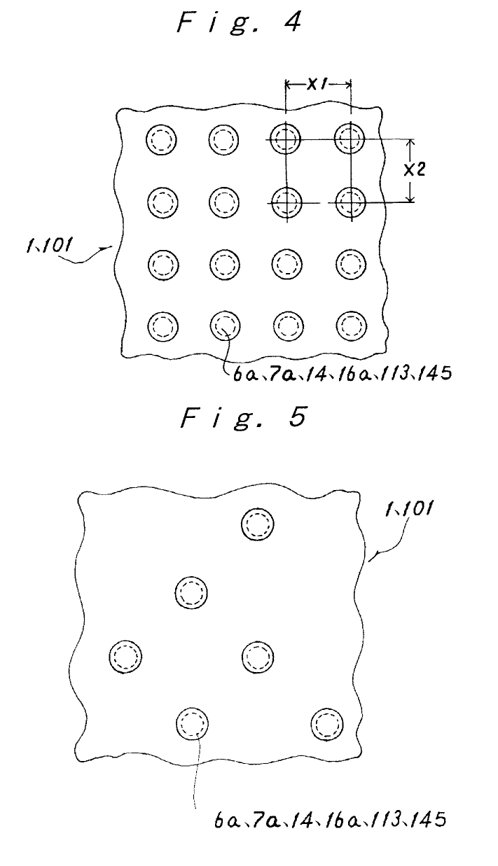

FIG. 1(a) to FIG. 1(c) are explanatory views showing the formation of a hole and an electroplating step, FIG. 2 and FIG. 3 are sectional views of a substrate and FIG. 4 and FIG. 5 are plan views showing an example of a multilayer substrate for a buildup with a via.

As shown by a sectional view in FIG. 1(a), a substrate (1) is prepared by laminating a copper layer (2) and an insulation resin layer (3), wherein the copper layer (2) is made of a copper foil of 9 μm in thickness and the insulation resin layer (3) is made of an FR4 Grade epoxy type resin of 80 μm in thickness.

As shown by a sectional view in FIG. 1(b), a hole (4) reaching the copper layer (2) is formed in the insulation resin layer (3) at a desired position of the substrate (1) by a UV-YAG laser (5).

Next, the surface of the insulation resin layer (3) and the inside wall surface of the hole (4) is performed by desmearing treatment and then by electroless plating or activating treatment, thereby enabling copper electroplating on the substrate (1).

In the copper electroplating, as shown by a perspective view in FIG. 1(c), the base material (1) in which the hole (4) is opened is oscillated circularly as shown by the arrow (A) in a copper plating bath. The hole (4) of the base material (1) is also oscillated circularly as shown by the arrow (A), thereby generating a vortex flow in the copper plating solution inside the hole (4). The vortex flow of the copper plating solution inside the hole (4) ensures that the flow rate of the copper plating solution on the inside wall surface of the hole (4) is higher than the flow rate on the surface (3a) of the insulation resin layer (3). Specifically, the flow rate of the copper plating solution on the inside wall surface of the hole (4) becomes about 1.1 to 2.0 times the flow rate on the surface (3a) of the insulation resin layer (3).

Such an increase in the flow rate of the copper plating solution on the inside wall surface of the hole (4) leads to the result that the copper ion diffusion layer (zone reduced in the concentration of copper ions in the copper plating solution) in the very vicinity of the inside wall surface of the hole (4) becomes thinner than the copper ion diffusion layer on the surface (3a) of the insulation resin layer (3), so that the electrodeposition rate (electrodeposition current) on the inside wall surface of the hole (4) is increased.

As shown by a partly enlarged sectional view in FIG. 2, an electrodeposition layer (7a) formed on the inside wall surface of the hole and the copper layer (2) on the bottom is thicker than an electrodeposition layer (7b) on the surface of the insulation resin layer (3) by oscillating the base material (1), on which the hole (4) is opened, in the copper plating bath as shown by the arrow (A) as mentioned above.

Also, the hole (4) of the base material (1) is oscillated circularly as shown in the arrow (A) to generate a vortex flow of the copper plating solution inside of the hole (4), thereby producing no thin portion of an electrodeposition layer on the end of the bottom of the hole. Specifically, the thin electrodeposition layer portion (245d) which is produced in conventional copper plating as shown in FIG. 24 is never produced.

It is to be noted that although the electrodeposition layer (7b) on the surface of the insulation resin layer (3) rises as shown by (7b′)on the hole, this portion may be flattened, if necessary, by polishing.

The sectional view of FIG. 3 shows a specific example of the size of the substrate for a buildup with a via (1) which substrate is formed in the above-mentioned manner. A substrate for a buildup was obtained in which the thickness of the insulation resin layer (3) was 80 μm, the thickness t3 of the copper layer (2) was 9 μm, the interval L1 between the holes was 500 μm, the diameter φ of the hole was 50 μm, the thickness t2 of the electrodeposition layer (7a) formed on the inside wall surface of the hole and on the copper layer (2) at the bottom was 10 μm and the thickness t1 of the electrodeposition layer (7b) on the surface of the insulation resin layer (3) was 8 μm.

Also, a substrate for a buildup was obtained in which the thickness of the insulation resin layer (3) was 40 μm, the thickness t3 of the copper layer (2) was 5 μm, the interval L1 between the holes was 300 μm, the diameter φ of the hole was 30 μm, the thickness t2 of the electrodeposition layer (7a) formed on the inside wall surface of the hole and on the copper layer (2) at the bottom was 6 μm and the thickness t1 of the electrodeposition layer (7b) on the surface of the insulation resin layer (3) was 5 μm.

As mentioned above, a buildup substrate micro-sized more greatly than those currently in use could be produced. The result of the evaluation of reliability as to interlayer electrical connection was 99% or more in yield. In the case of a conventional method, the result of the evaluation of reliability was 80 to 90% in yield.

Also, with regard to the substrate for a buildup with a via which substrate is formed in the above-mentioned manner, a specific example of the arrangement of holes will be given wherein an electrodeposition layer thicker than the electrodeposition layer formed on the insulation resin layer thereof is formed on the inside wall surface of the holes.

The substrate for a buildup with a via as shown in FIG. 4 comprises the base material (1) in which an electrodeposition layer is formed on the surface of the insulation resin layer and plural holes (vias) provided with the electrodeposition layer (7a) formed on the inside wall surface thereof are arranged at predetermined intervals (X1) and (X2). This substrate for a buildup is used as a universal substrate (multipurpose substrate). When a circuit is formed on the substrate (1), it is formed using holes disposed at the positions required for the formation of the circuit among these plural holes.

A substrate for a buildup with via as shown in FIG. 5 comprises the substrate (1) in which an electrodeposition layer (7b) is formed on the surface of the insulation resin layer and holes provided with an electrodeposition layer formed on the inside wall surface thereof are formed at only the positions required for the formation of a circuit. This substrate for a buildup is manufactured as a substrate for a specified circuit.

### Example 2

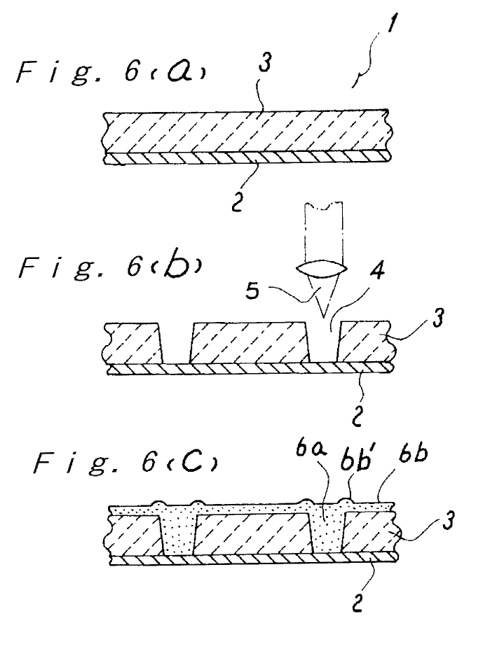

Example 2 according to the present invention will be explained with reference to FIG. 6(a) to FIG. 6(c). Example 2 shows a substrate for a buildup with a via wherein a hole is filled up with an electrodeposition layer.

As shown by a sectional view in FIG. 6(a), a substrate (1) is prepared by laminating a copper layer (2) and an insulation resin layer (3), wherein the copper layer (2) is made of a copper foil of 5 μm in thickness and the insulation resin layer (3) is made of an FR4 Grade epoxy type resin of 40 μm in thickness. In addition, as shown by a sectional view in FIG. 6(b), a hole (4) reaching the copper layer (2) is opened on the insulation resin layer (3) of the substrate (1) by using a laser (5).

Next, the surface of the insulation resin layer (3) and the inside wall surface of the hole (4) is performed by desmearing treatment and roughing treatment and then by electroless plating or activating treatment to enable the copper electroplating of the substrate (1).

Next, the substrate (1) on which the hole (4) is opened is oscillated circularly in a copper plating bath to carry out electroplating and then, as shown by a sectional view in FIG. 6(c), the hole (4) is filled up with an electrodeposition layer (6a) and an electrodeposition layer (6b) is formed on the surface of the insulation resin layer (3).

The copper electroplating is, as explained in the above-mentioned Example 1, performed by oscillating the substrate (1) circularly in a copper plating bath. A vortex flow of the copper plating solution is generated inside the hole (4) and the flow rate of the copper plating solution on the inside wall surface of the hole (4) is higher than the flow rate on the surface (3a) of the insulation resin layer (3), with the result that the copper ion diffusion layer (zone reduced in the concentration of copper ions in the copper plating solution) in the very vicinity of the inside wall surface of the hole (4) becomes thinner than the copper ion diffusion layer on the surface (3a) of the insulation resin layer (3), so that the electrodeposition rate (electrodeposition current) on the inside wall surface of the hole (4) is increased. It is intended to fill up the hole (4) with the electrodeposition layer (6a) by continuing electroplating with oscillating the substrate (1) circularly in the copper plating bath.

This substrate for a buildup with a via having the structure in which the hole is filled up with the electrodeposition layer (6a) ensures more firm interlayer electrical connection and has high reliability as to electrical connection.

It is to be noted that as shown in FIG. 6(c), the electrodeposition layer (6b) on the surface of the insulation resin layer (3) rises above the hole as shown by (6b′) and therefore this part is, if necessary, flattened by polishing.

### Example 3

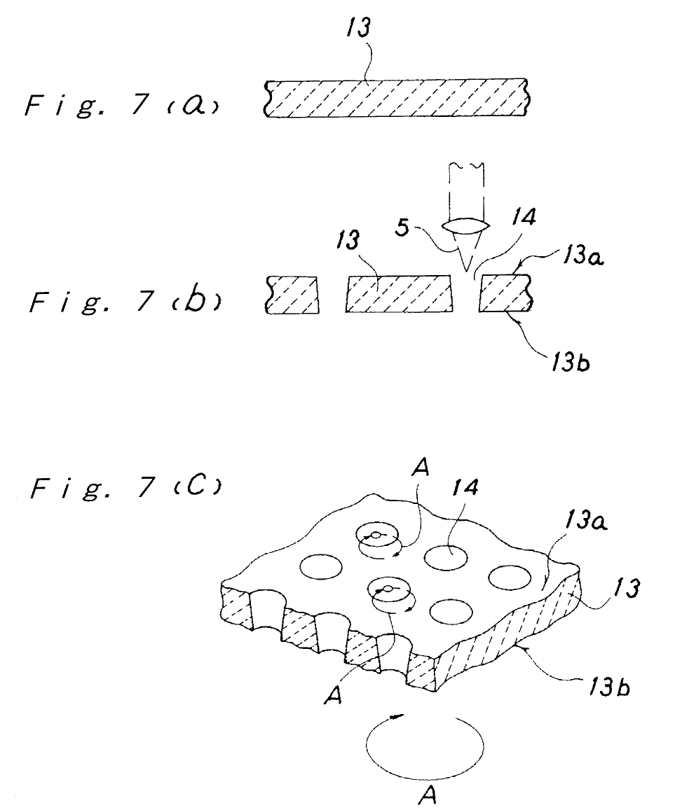

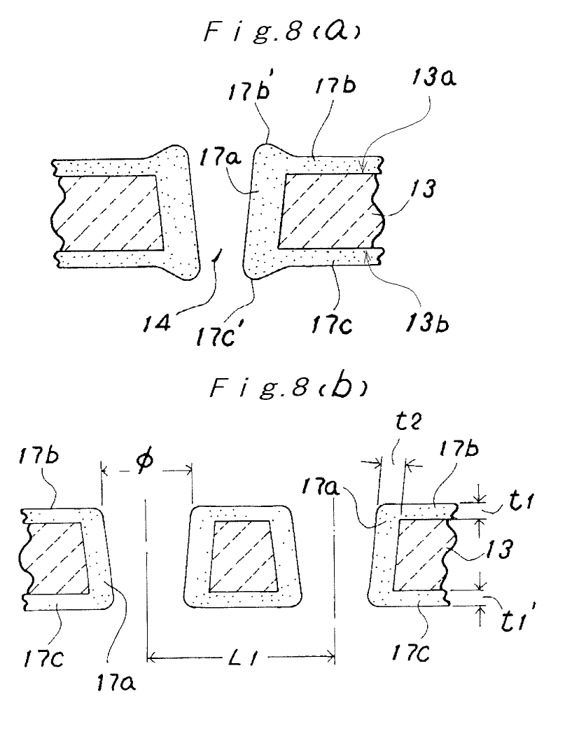

Example 3 according to the present invention will be explained with reference to FIG. 7 and FIG. 8.

In Example 3, a through-hole is formed in an insulation resin layer and an electrodeposition layer is formed on the inside wall surface of the through-hole and on both surfaces of the insulation resin layer by circular oscillation electroplating to manufacture a multilayer substrate for a buildup with a via.

FIG. 7(a) to FIG. 7(c) are explanatory views showing the formation of a hole and an electroplating step and FIG. 8(a) and FIG. 8(b) are sectional views of the resulting substrate.

As shown by the sectional view in FIG. 7(b), a through-hole (14) is formed at a desired position of an insulation resin layer (13) whose sectional view is shown in FIG. 7(a) by using a UV-YAG laser (5). Next, the upper surface (13a) and lower surface (13b) of the insulation resin layer (13) and the inside wall surface of the through-hole (14) are performed by desmearing treatment and roughing treatment and then by electroless plating or activating treatment to enable the copper electroplating of the substrate (13).

The copper electroplating is, as shown by the perspective view in FIG. 7(c), carried out by circularly oscillating the insulation resin layer (13), on which the through-hole (14) is formed, in the copper plating bath as shown by the arrow (A). The through-hole (14) is also oscillated circularly as shown by the arrow (A), thereby generating a vortex flow of the copper plating solution inside the through-hole (14). The vortex flow of the copper plating solution inside the through-hole (14) allows the flow rate of the copper plating solution to be higher on the inside wall surface of the through-hole (14) than on both the upper surface (13a) and lower surface (13b) of the insulation resin layer (13). Specifically, the flow rate of the copper plating solution on the inside wall surface of the through-hole (14) becomes about 1.1 to 2.0 times the flow rate of the copper plating solution on the upper surface (13a) and lower surface (13b) of the insulation resin layer (13).

As described above, the increase in the flow rate of the copper plating solution on the inside wall surface of the through-hole (14) brings about the result that the copper ion diffusion layer (zone reduced in the concentration of copper ions in the copper plating solution) in the very vicinity of the inside wall surface of the through-hole (14) becomes thinner than the copper ion diffusion layer on the upper surface (13a) and lower surface (13b) of the insulation resin layer (13), so that the electrodeposition rate (electrodeposition current) on the inside wall surface of the through-hole (14) is increased.

As described above, the insulation resin layer (13) on which the through-hole (14) is opened is oscillated circularly as shown by the arrow (A) in the copper plating solution, whereby a copper plating (17a) is electrodeposited on the inside wall surface of the through-hole (via) (14) of the insulation resin layer (13) and a copper plating (17b) and a copper plating (17c) are formed on the upper surface (13a) and the lower surface (13b) respectively as shown by the sectional view in FIG. 8(a). The copper plating (17a) which is the electrodeposition layer formed on the inside wall surface of the through-hole (14) is formed in a thickness higher than the copper plating (17b) formed on the upper surface (13a) and the copper plating (17c) formed on the lower surface (13b).

As the copper plating (17b) formed on the upper surface (13a) of the insulation resin layer (13) rises as shown by (17b′) at the corner of the through-hole (14) and also the copper plating (17c) of the lower surface (13b) rises as shown by (17c′), these portions, if necessary, may be flattened by polishing.

Specific examples of the size of the substrate for a buildup with a via which substrate is formed in the above manner will be explained with reference to the sectional view of FIG. 8(b).

A substrate for a buildup was obtained in which as the insulation resin layer (13), an epoxy resin equivalent to an FR4 which resin had a thickness of 50 μm was used, a through-hole having the following characteristics was formed: hole diameter φ: 50 μm and interval L1 between holes: 300 μm and the following electrodeposition layers were formed by circular oscillation electroplating: the thickness t2 of the electrodeposition layer (17a) of the inside wall surface of the through-hole: 8.2 μm, the thickness t1 of the electrodeposition layer (17b) of the upper surface: 7.6 μm and the thickness t1′ of the electrodeposition layer (17c) of the lower surface: 7.4 μm.

Also, a substrate for a buildup was obtained in which as the insulation resin layer (13), a polyimide resin having a thickness of 40 μm was used, a through-hole having the following characteristics was formed: hole diameter φ: 30 μm and interval L1 between holes: 200 μm and the following electrodeposition layers were formed by circular oscillation electroplating: the thickness t2 of the electrodeposition layer (17a) of the inside wall surface of the through-hole: 6.1 μm, the thickness t1 of the electrodeposition layer (17b) of the upper surface: 5.6 μm and the thickness t1′ of the electrodeposition layer (17c) of the lower surface: 5.8 μm.

The electrodeposition layer (17a) formed on the inside wall surface of this through-hole was formed in a thickness higher than the electrodeposition layer (17b) of the upper surface (13a) and the electrodeposition layer (17c) of the lower surface (13b). Also, the electrodeposition layer (17b) of the upper surface (13a) almost had the same thickness as the electrodeposition layer (17c) of the lower surface (13b), with the result that no warpage was caused by plating stress.

### Example 4

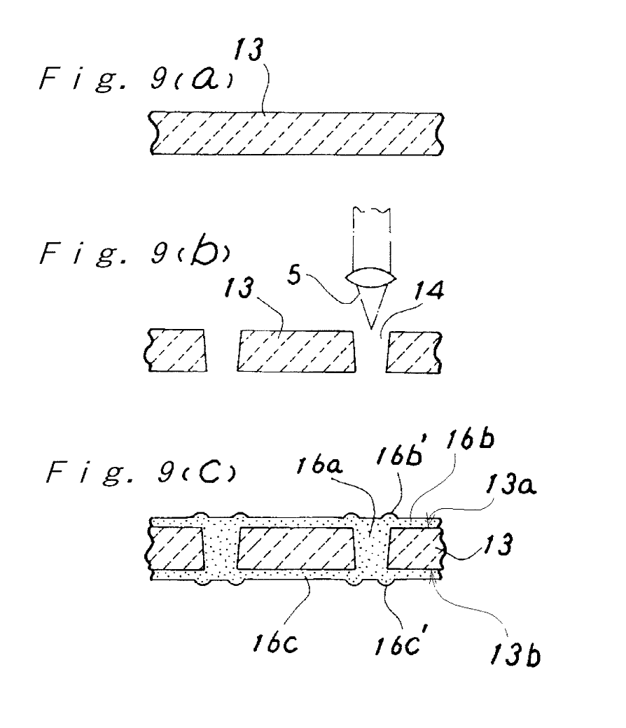

Example 4 according to the present invention will be explained with reference to FIG. 9(a) to FIG. 9(c).

Example 4 represents a multilayer substrate for a buildup with a via wherein the through-hole is filled up with an electrodeposition layer.

As shown by the sectional view in FIG. 9(b), a through-hole (14) is formed at a desired position of an insulation resin layer (13) whose sectional view is shown in FIG. 9(a) by using a UV-YAG laser (5). Next, the upper surface (13a) and lower surface (13b) of the insulation resin layer (13) and the inside wall surface of the through-hole (14) is performed by desmearing treatment and roughing treatment and then by electroless plating or activating treatment to enable copper electroplating.

Next, the insulation resin layer (13) on which the through-hole (14) is opened is oscillated circularly in a copper plating bath to carry out electroplating, thereby filling up the through-hole (14) with the electrodeposition layer (16a) and forming an electrodeposition layer (16b) on the upper surface (13a) of the insulation resin layer (13) and an electrodeposition layer (16c) on the lower surface (13b) of the insulation resin layer (13) as shown by the sectional view in FIG. 9(c).

The copper electroplating is, as explained in the above Example 3, carried out by oscillating the insulation resin layer (13) circularly in the copper plating bath. An electrodeposition layer is formed on the inside wall surface of the through-hole (14) and the through-hole (14) is filled up with the electrodeposition layer (16a) by continuing electroplating with circular oscillation.

The substrate for a buildup with a via on which the through-hole (14) is filled up with the electrodeposition layer (16a) has high reliability as to electrical connection.

### Example 5

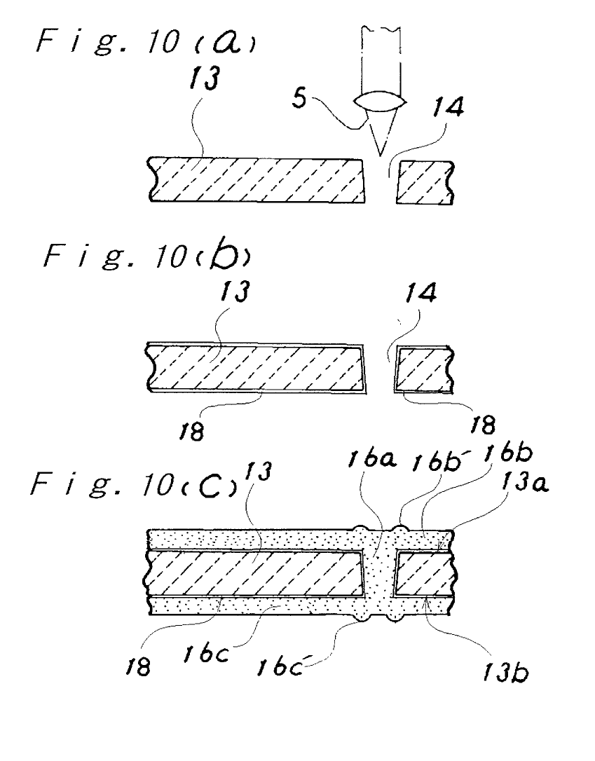

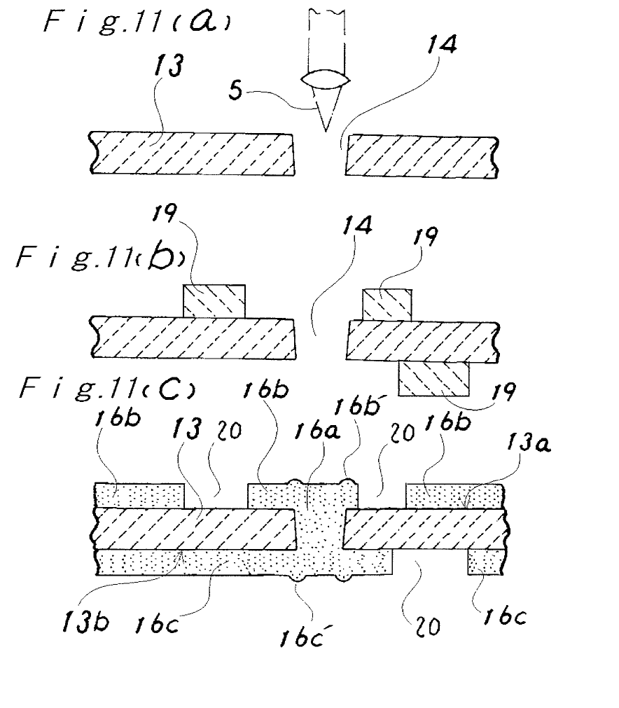

Example 5 according to the present invention will be explained with reference to FIG. 10(a) to FIG. 10(c).

Example 5 shows another example of a multilayer substrate for a buildup with a via wherein a through-hole is filled up with an electrodeposition layer.

As shown by a sectional view in FIG. 10(a), a through-hole (14) having a hole diameter of 30 μm is formed at a desired position of an insulation resin layer (13) made of a polyimide film (thickness: 50 μm) by using a YAG laser (5). The upper surface (13a) and lower surface (13b) of the insulation resin layer (13) and the inside wall surface of the through-hole (14) are performed by desmearing treatment using a potassium permanganate type desmearing solution and roughing treatment.

After that, as shown by a sectional view in FIG. 10(b), a copper sputtering film (18) having a thickness of about 0.3 μm is formed by copper sputtering on the upper surface (13a) and lower surface (13b) of the insulation resin layer (13) and on the inside wall surface of the through-hole (14) to enable copper electroplating.

Next, the insulation resin layer (13) provided with the copper sputtering film (18) is oscillated circularly in a copper plating bath to carry out electroplating, thereby filling up the through-hole (14) with the electrodeposition layer (16a) and forming an electrodeposition layer (16b) on the upper surface (13a) of the insulation resin layer (13) and an electrodeposition layer (16c) on the lower surface (13b) of the insulation resin layer (13) as shown by a sectional view in FIG. 10(c). Each of the electrodeposition layer (16b) and the electrodeposition layer (16c) has a thickness of 12 μm.

It is to be noted that the electrodeposition layer (16b) on the upper surface (13a) of the insulation resin layer (13) rises as shown by (16b′) at the corner of the through-hole (14) and the copper plating (16c) on the lower surface (13b) rises as shown by (16c′) and, if necessary, these parts may be flattened by polishing.

The copper electroplating is, as explained in the above Example 3, carried out by oscillating the insulation resin layer (13) circularly in the copper plating bath. An electrodeposition layer is formed on the inside wall surface of the through-hole (14) and the through-hole (14) is filled up with the electrodeposition layer (16a) by continuing electroplating with circular oscillation.

This method ensures that the substrate for a buildup with a via in which the through-hole (14) is filled up with the copper sputtering electrodeposition layer (16a) has high reliability as to electrical connection.

### Example 6

Example 6 according to the present invention will be explained with reference to FIG. 11(a) to FIG. 11(c).

Example 6 represents a multilayer substrate for a buildup with a via wherein a through-hole is filled up with an electrodeposition layer and a specified copper circuit is formed at the same time when the hole is filled.

As shown by a sectional view in FIG. 11(a), a through-hole (14) having a hole diameter of 60 μm is formed at a desired position of an insulation resin layer (13) made of an FR4 Grade epoxy type resin (thickness: 50 μm) by using a CO₂ laser (5). The upper surface (13a) and lower surface (13b) of the insulation resin layer (13) and the inside wall surface of the through-hole (14) are performed by desmearing treatment using a potassium permanganate type desmearing solution and roughing treatment and then by electroless copper plating (the thickness of copper: about 0.5 μm) to enable copper electroplating.

Thereafter, as shown by a sectional view in FIG. 11(b), a dry film (19) with a thickness of 40 μm is stuck to each specified position of the upper surface (13a) and lower surface (13b) of the insulation resin layer (13) to form a resist used at the time of copper plating. The resist comprising the dry film (19) is formed at the positions where a circuit section made of copper is not formed when forming a desired circuit.

Next, the insulation resin layer (13) provided with the resist made of the dry film (19) is oscillated circularly in a copper plating bath to carry out electroplating, thereby filling up the through-hole (14) with an electrodeposition layer (16a) and forming an electrodeposition layer (16b) on the upper surface (13a) of the insulation resin layer (13) and an electrodeposition layer (16c) on the lower surface (13b) of the insulation resin layer (13) to thereby performing via-hole-filling and the formation of a circuit at the same time. Each thickness of the electrodeposition layer (16b) and the electrodeposition layer (16c) is 30 μm.

Thereafter, the resist is removed by a usual method to obtain a multilayer substrate for a buildup in which a desired circuit is formed as shown by a sectional view in FIG. 11(c). In the figure, 20 represents a void portion left after the resist is removed. By this void section (20), a copper circuit by which the electrodeposition layers (among 16bs or 16cs) are electrically isolated is formed.

It is to be noted that the copper plating layer (16b) on the upper surface (13a) of the insulation resin layer (13) rises as shown by (16b′) at the corner of the through-hole (14) and the copper plating (16c) on the lower surface (13b) rises as shown by (16c′), if necessary, and these parts may be flattened by polishing.

The copper electroplating is, as explained in the above Example 3, carried out by oscillating the insulation resin layer (13) circularly in the copper plating bath. An electrodeposition layer is formed on the inside wall surface of the through-hole (14) and the through-hole (14) is filled up with the electrodeposition layer (16a) by continuing electroplating with circular oscillation.

This method ensures that the substrate for a buildup with a via on which the through-hole (14) is filled up with the copper sputtering electrodeposition layer (16a) has high reliability as to electrical connection and besides the above merit, has high productivity because a specified circuit can be formed at the same time when filling up the through-hole.

As mentioned above, the substrate for a buildup with a via which substrate is obtained in Example 2 on which a hole reaching a copper layer of an insulation resin layer is filled up with an electrodeposition layer, in Example 3 in which an electrodeposition layer is formed in a through-hole on an insulation resin layer, in Example 4 on which a through-hole is filled up with an electrodeposition layer or in Example 5 is, in the same manner as explained in the above Example 1, used as a universal substrate (multipurpose) by arranging plural through-holes at predetermined intervals as shown in FIG. 4 or used as a substrate for a specific circuit by forming through-holes only at the positions required for forming a circuit as shown in FIG. 5.

### Example 7

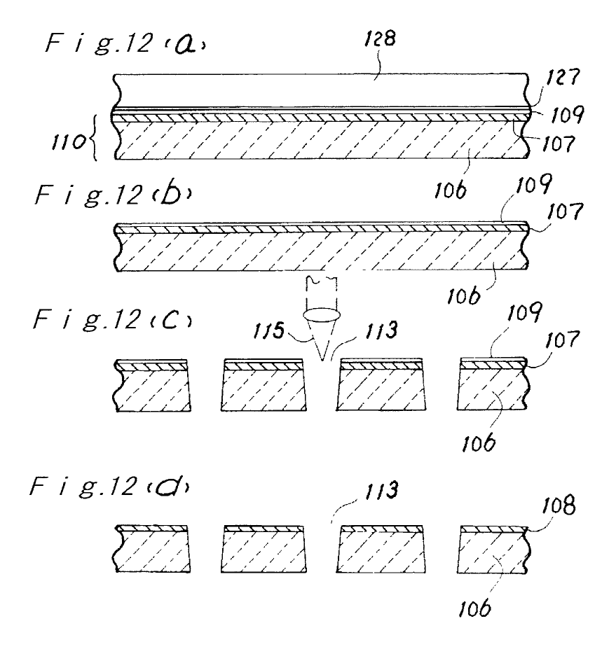

Example 7 according to the present invention will be explained with reference to FIG. 12 to FIG. 14.

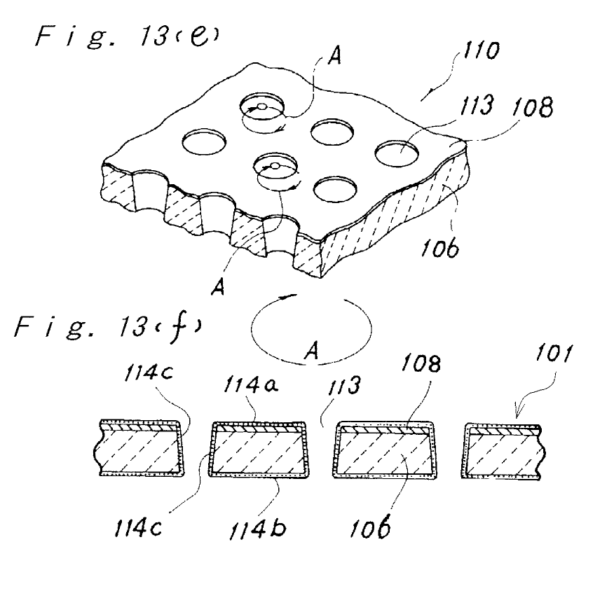

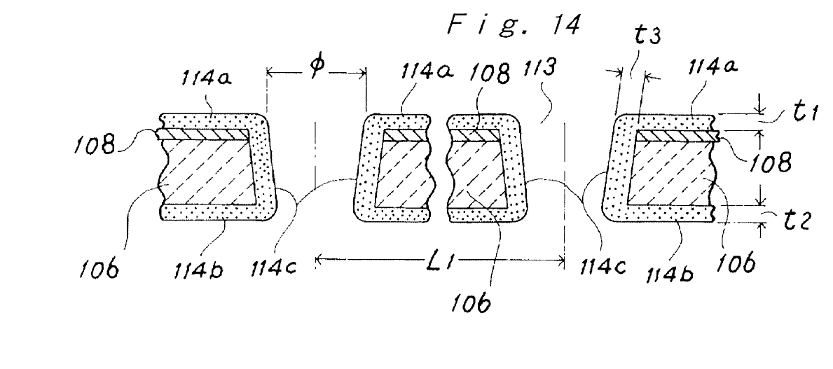

FIG. 12(a) to FIG. 12(d) and FIG. 13(e) are explanatory views showing the formation of a through-hole and a circular oscillation electroplating and FIG. 13(f) and FIG. 14 are partly sectional views of the obtained substrate.

As shown by the sectional view in FIG. 12(a), a base material (110) is bound with a carrier copper foil (128). The base material (110) is prepared by laminating an extra thin copper foil (107) on one surface of an insulation resin layer (106) by a hot press. The insulation resin layer (106) is made of an epoxy resin equivalent to an FR4 and has a thickness of 50 μm. The extra thin copper foil (107) has a thickness of 5 μm and the surface roughness of the copper foil (107) on the side which is in contact with the insulation resin layer (106), namely, Rz is 2.5 (μm). The extra thin copper foil (107) is provided with a Co—Cu alloy plating (109) of 0.05 to 0.1 μm in thickness by treatment enabling good laser workability.

Also, the carrier copper foil (128) has a thickness of 35 μm and is provided with a peelable layer (127) having a thickness of about 0.01 μm.

The base material (110) provided with the extra thin copper foil (107) and the Co—Cu alloy plating (109) on one surface of the insulation resin layer (106) is bound with the carrier copper foil (128) provided with the peelable layer (127), thereby making it easy to handle.

As shown by the sectional view in FIG. 12(b), the carrier copper foil is peeled off to make the base material (110) provided with the extra thin copper foil (107) and the Co—Cu alloy plating (109) on one surface of the insulation resin layer (106).

Next, as shown by the sectional view in FIG. 12(c), a through-hole (113) is formed from the side of the extra thin copper foil (107) provided with the Co—Cu alloy plating (109) enabling good laser workability by laser via-working using a UV-YAG laser (115).

Next, etching is carried out to make an extra thin copper foil (108) having a thickness of 2.2 μm as shown by the sectional view in FIG. 12(d).

Then, the base material on which the through-hole (113) is formed and which base material is provided with the extra thin copper foil (108), which has been made to have a thickness of 2.2 μm by etching, on one surface of the insulation resin layer (106) is performed by desmearing treatment, electroless plating or activating treatment to enable the copper electroplating of the base material (110).

Next, as shown by the perspective view in FIG. 13(e), the base material (110) on which the through-hole (113) has been formed and which has been performed by desmearing treatment and electroless plating or activating treatment is oscillated circularly as shown by the arrow (A) in a copper plating bath to carry out circular oscillation electroplating. By making the base material (110) oscillate circularly as shown by the arrow (A), the through-hole (113) of the base material (110) is oscillated circularly as shown by the arrow (A). This generates a vortex flow of the copper plating solution of the through-hole (113). The vortex flow of the copper plating solution inside the through-hole (113) ensures that the flow rate of the copper plating solution on the inside wall surface of the through-hole (113) is higher than the flow rate on the surface of the extra thin copper foil (108) and on the surface of the insulation resin layer (106). Specifically, the flow rate of the copper plating solution on the inside wall surface of the through-hole (113) becomes about 1.1 to 2.0 times the flow rate on the surface of the insulation resin layer (106).

The increase in the flow rate of the copper plating solution on the inside wall surface of the through-hole (113) brings about the result that the copper ion diffusion layer (zone reduced in the concentration of copper ions in the copper plating solution) in the very vicinity of the inside wall surface of the through-hole (113) becomes thinner than the copper ion diffusion layer on the surface of the insulation resin layer (106), so that the electrodeposition rate (electrodeposition current) on the inside wall surface of the through-hole (113) is increased.

As shown by the sectional view in FIG. 13(f), a multilayer substrate for a buildup (101) with a via was obtained wherein an electrodeposition layer (114a) was formed on the surface of the extra thin copper foil (108), an electrodeposition (114b) was formed on the surface of the insulation resin layer (106) and an electrodeposition layer (114c) was formed on the inside wall surface of the through-hole (113) by oscillating the base material (110) circularly as shown by the arrow (A) in the copper plating bath.

With regard to the multilayer substrate for a buildup with a via, its concrete size will be explained with reference to the partly enlarged sectional view shown in FIG. 14.

Each size was as follows: interval L1 between the through-holes (113)=200 μm, diameter φ of the through-hole (113)=50 μm, thickness of the insulation resin layer (106)=50 μm, thickness of the extra thin copper foil (108)=2.2 μm, thickness t3 of the electrodeposition layer (114c) on the inside wall surface of the through-hole (113)=8.2 μm, thickness t1 of the electrodeposition layer (114a) on the surface of the extra thin copper foil (108)=10.5 μm, thickness t2 of the electrodeposition layer (114b) on the surface of the insulation resin layer (106)=7.4 μm and each peeling strength of the copper layer on the side of the extra thin copper foil (108) and on the side of the insulation resin layer (106): 1.25 kg/cm and 0.75 kg/cm respectively.

This multilayer substrate for a buildup with a via was a substrate in which the peeling strength of the copper layer on the side of the extra thin copper foil (108) was 0.9 kg/cm or more which was enough to stand against the packaging of parts. Also, the electrodeposition layer (114c) on the inside wall surface of the through-hole (113) was formed in a thickness higher than the electrodeposition layer (114b) of the insulation resin layer (106) and the multilayer substrate had high reliability as to interlayer electrical connection in the finned through-hole (113).

### Example 8

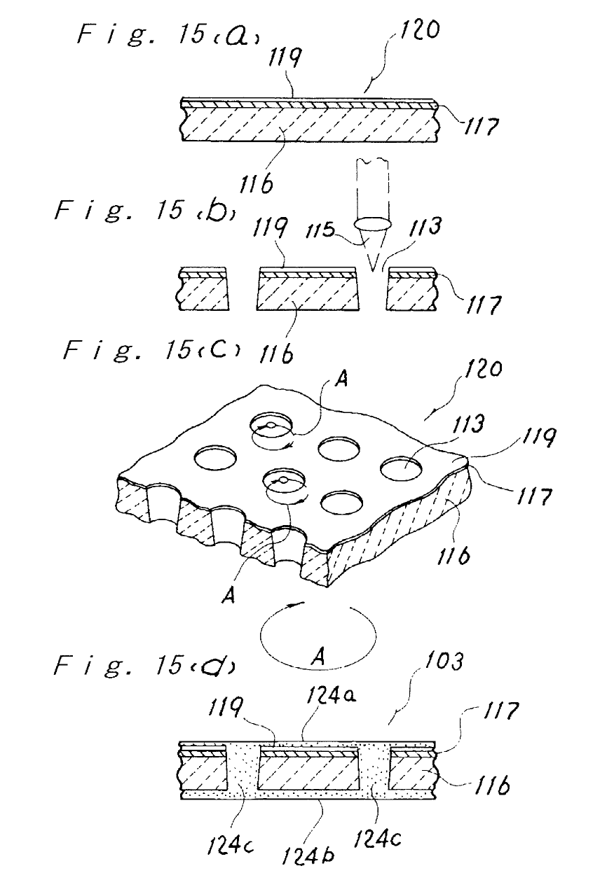

Example 8 according to the present invention will be explained with reference to FIG. 15 and FIG. 16.

FIG. 15(a) to FIG. 15(c) are explanatory views showing the formation of a through-hole and a circular oscillation electroplating step and FIG. 15(d) and FIG. 16 are sectional views of the obtained substrate for a buildup.

FIG. 15(a) is a sectional view showing a base material (120), which is prepared by laminating an extra thin copper foil (117) on one surface of an insulation resin layer (116) by a hot press. The insulation resin layer (116) is made of a polyimide and has a thickness of 40 μm. The extra thin copper foil (117) has a thickness of 5 μm and the surface roughness of the copper foil (117) on the side which is in contact with the insulation resin layer (116), namely, Rz is 1.9 (μm). The extra thin copper foil (117) is provided with a Co—Cu alloy plating (119) about 0.05 to 0.1 μm in thickness by treatment enabling good laser workability.

The base material (120) is bound with the carrier copper foil of 35 μm in thickness which is provided with a peelable layer of about 0.01 μm in thickness and prepared by peeling off from the peelable layer.

Next, as shown by the sectional view in FIG. 15(b), a through-hole (113) is formed from the side of the extra thin copper foil (117) provided with the Co-Cu alloy plating (119) enabling good laser workability by laser via-working using a UV-YAG laser (115).

Then, the base material on which the through-hole (113) is formed and which is provided with the extra thin copper foil (117) on one surface of the insulation resin layer (116) is performed by desmearing treatment, electroless plating or activating treatment to enable the copper electroplating of the base material.

Next, as shown by the perspective view in FIG. 15(c), the base material (120) which has been performed by desmearing treatment and electroless plating or activating treatment is oscillated circularly as shown by the arrow (A) in a copper plating bath to carry out circular oscillation electroplating. By making the base material (120) oscillate circularly as shown by the arrow (A), the through-hole (113) of the base material (120) is oscillated circularly as shown by the arrow (A). This generates a vortex flow of the copper plating solution inside the through-hole (113). The vortex flow of the copper plating solution inside of the through-hole (113) ensures that the flow rate of the copper plating solution on the inside wall surface of the through-hole (113) is higher than the flow rate on the surface of the extra thin copper foil (117) and on the surface of the insulation resin layer (116). The increase in the flow rate of the copper plating solution on the inside wall surface of the through-hole (113) brings about the result that the copper ion diffusion layer (zone reduced in the concentration of copper ions in the copper plating solution) in the very vicinity of the inside wall surface of the through-hole (113) becomes thinner than the copper ion diffusion layer on the surface of the insulation resin layer (116), so that the electrodeposition rate (electrodeposition current) on the inside wall surface of the through-hole (113) is increased.

As shown by the sectional view in FIG. 15(d), by carrying on such circular oscillation electroplating, a multilayer substrate for a buildup with a via was obtained wherein the through-hole (113) was filled up with an electrodeposition layer (124c), an electrodeposition layer (124a) was formed on the surface of the extra thin copper foil (117) and an electrodeposition (124b) was formed on the surface of the insulation resin layer (116).

With regard to the multilayer substrate for a buildup with a via, its concrete size will be explained with reference to the enlarged sectional view shown in FIG. 16.

Each size was as follows: interval L1 between the through-holes (113)=150 μm, diameter φ of the through-hole (113)=30 μm, thickness of the insulation resin layer (116)=50 μm, thickness of the extra thin copper foil (117)=4.8 μm, through-hole (113): filled up with the electrodeposition layer (124c), thickness t1 of the electrodeposition layer (124a) on the surface of the extra thin copper foil (117)=15.3 μm, thickness t2 of the electrodeposition layer (124b) on the surface of the insulation resin layer (116)=12.8 μm and each peeling strength of the copper layer on the side of the extra thin copper foil (117) and on the side of the insulation resin layer (116): 1.25 kg/cm and 0.67 kg/cm respectively. This multilayer substrate for a buildup with a via was a substrate in which the peeling strength of the copper layer on the side of the extra thin copper foil (117) was 0.9 kg/cm or more which was enough to stand against the packaging of parts. Also, the through-hole (113) was filled up with the electrodeposition layer (124c) and the multilayer substrate had high reliability as to interlayer electrical connection in the finned through-hole (113).

### Example 9

Example 9 according to the present invention will be explained with reference to FIG. 17.

FIG. 17(a) to FIG. 17(c) are sectional views showing a step of forming a through-hole, FIG. 17(d) is a perspective view showing a circular oscillation electroplating step and FIG. 17(e) is a sectional view of the obtained substrate.

The sectional view of FIG. 17(a) shows a base material (130), which is prepared by laminating a copper foil (132) on one surface of an insulation resin layer (131) by a hot press. The insulation resin layer (131) is made of an epoxy resin equivalent to an FR4 and has a thickness of 50 μm. The copper foil (132) has a thickness of 12 (μm) and the surface roughness of the copper foil (132) on the side which is in contact with the insulation resin layer (131), namely, Rz is 2.5 (μm). The copper foil (132) is provided with a Co-Cu alloy plating (135) of 0.05 to 0.1 μm in thickness by treatment enabling good laser workability.

Next, as shown by the sectional view in FIG. 17(b), a through-hole (113) is formed from the side of the copper foil (132) provided with the Co-Cu alloy plating (135) enabling good laser workability by laser via-working using a UV-YAG laser (115).

Next, etching is carried out to obtain an extra thin copper foil (133) having a thickness of 2.8 μm as shown by the sectional view in FIG. 17(c). Then, the base material on which the through-hole (113) is formed and which is provided with the extra thin copper foil (133), which has been made to have a thickness of 2.8 μm by etching, on one surface of the insulation resin layer (131) is performed by desmearing treatment, electroless plating or activating treatment to enable the copper electroplating of the base material.

Next, as shown by the perspective view in FIG. 17(d), the base material (130) on which the through-hole (113) had been formed and which had been performed by desmearing treatment, electroless plating or activating treatment was oscillated circularly as shown by the arrow (A) in a copper plating bath to carry out circular oscillation electroplating in the same manner as in the above-mentioned Example 7, to obtain a multilayer substrate for a buildup with a via wherein an electrodeposition layer (134a) was formed on the surface of the extra thin copper foil (133), an electrodeposition (134b) was formed on the surface of the insulation resin layer (131) and an electrodeposition layer (134c) was formed on the inside wall surface of the through-hole (113) as shown by a sectional view in FIG. 17(e).

This multilayer substrate for a buildup with a via had the following characteristics: interval L1 between the through-holes (113)=200 μm, diameter φ of the through-hole (113)=50 μm, thickness of the electrodeposition layer (134c) on the inside wall surface of the through-hole (113) was 8.1 μm, thickness t of the electrodeposition layer (134a) on the surface of the extra thin copper foil was 10.2 μm, thickness of the electrodeposition layer (134b) on the surface of the insulation resin layer (131) was 7.5 μm and the peeling strength of the copper layer: 1.15 kg/cm on the side of the extra thin copper foil (133) and 0.69 kg/cm on the side of the insulation resin layer (131). Namely, the peeling strength of the copper layer on the side of the extra thin copper foil (133) was 0.9 kg/cm or more which was enough to stand against the packaging of parts, the electrodeposition layer (134c) on the inside wall surface of the through-hole (113) was formed in a thickness higher than the electrodeposition layer (134b) on the insulation resin layer (131) and the multilayer substrate had high reliability as to interlayer electrical connection in the finned through-hole (113).

### Example 10

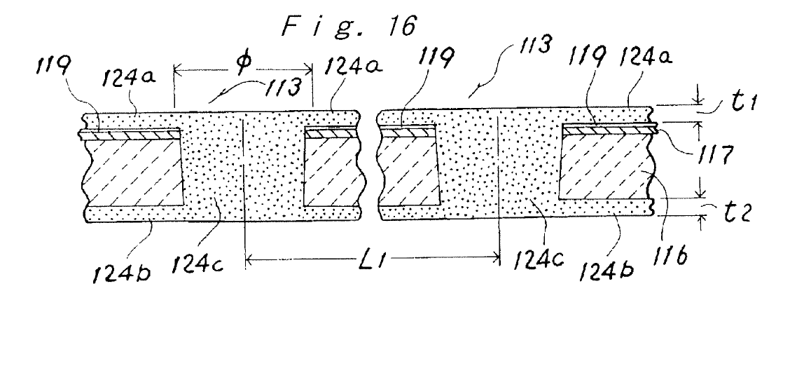

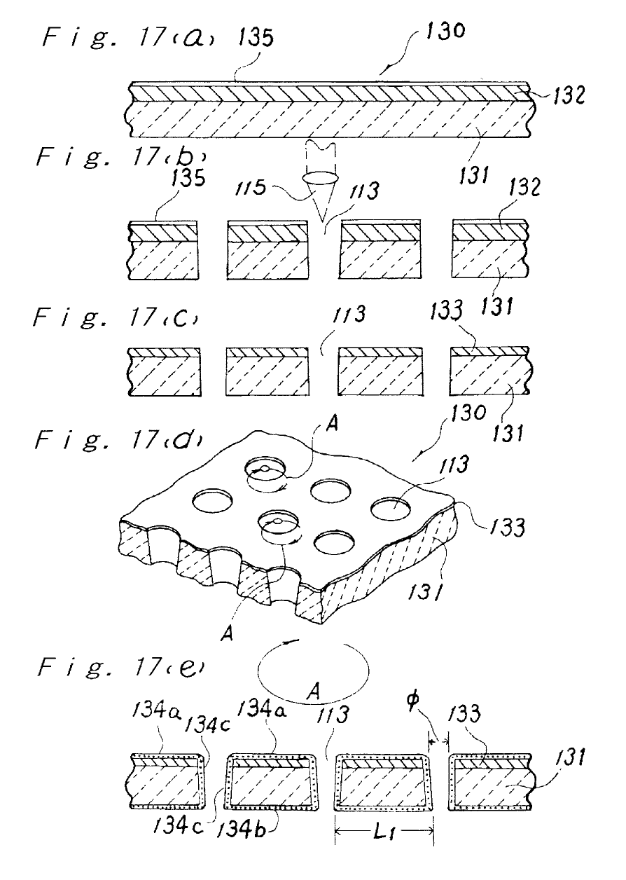

Example 10 of the present invention will be explained with reference to FIG. 18.

FIG. 18(a) to FIG. 18(c) are sectional views showing a step of forming a hole, FIG. 18(d) is a perspective view showing a circular oscillation electroplating step and FIG. 18(e) is a sectional view of the obtained substrate.

As shown by the sectional view in FIG. 18(a), a base material (140) is bound with a carrier copper foil (128). The base material (140) is prepared by laminating an extra thin copper foil (142) on one surface of an insulation resin layer (141) by a hot press. The insulation resin layer (141) is made of an epoxy resin equivalent to an FR4 and has a thickness of 50 μm. The extra thin copper foil (142) has a thickness of 5 μm and the surface roughness of the extra thin copper foil (142) on the side which is in contact with the insulation resin layer (141), namely, Rz is 2.7 (μm).

Also, the carrier copper foil (128) has a thickness of 35 μm and is provided with a peelable layer (127) having a thickness of about 0.01 μm.

As shown by the sectional view in FIG. 18(b), the carrier copper foil is peeled off to make the base material (140) provided with the extra thin copper foil (142) on one surface of the insulation resin layer (141).

Next, as shown by the sectional view in FIG. 18(c), a hole (145) reaching the extra thin copper foil (142) is formed from the side of the insulation resin layer (141) by laser via-working using a UV-YAG laser (115).

Next, the extra thin copper foil (142) is thinned by etching to form an extra thin copper foil with a thickness of 3.2 μm. Then, the base material on which the hole (145) is formed and which is provided with the extra thin copper foil (143), which has been made to have a thickness of 3.2 μm by etching, on one surface of the insulation resin layer (141) is performed by desmearing treatment, electroless plating or activating treatment to enable the copper electroplating of the base material.

Next, as shown by the perspective view in FIG. 18(d), the base material (140) on which the hole (145) has been formed and which has been performed by desmearing treatment, electroless plating or activating treatment is oscillated circularly as shown by the arrow (A) in a copper plating bath to carry out circular oscillation electroplating.

By allowing the base material (140), on which the hole (145) is formed, to oscillate circularly as shown by the arrow (A) in the copper plating bath, the hole (145) is oscillated circularly as shown by the arrow (A). This generates a vortex flow of the copper plating solution inside of the hole (145). The vortex flow of the copper plating solution inside of the hole (145) ensures that the flow rate of the copper plating solution on the inside wall surface of the hole (145) is higher than the flow rate on the surface of the insulation resin layer (141).

As shown by the sectional view in FIG. 18(e), electrodeposition layers (144a) to (144c) are formed by oscillating the base material (140) circularly as shown by the arrow (A) in the copper plating bath.

This multilayer substrate for a buildup with a via had the following characteristics: interval L1 between the holes (145): 200 μm, diameter φ of the hole (145)=50 μm, thickness of the electrodeposition layer (144c) on the inside wall surface of the hole (145) was 8.2 μm, thickness t1 of the electrodeposition layer (144a) on the surface of the extra thin copper foil (143) was 11.5 μm, thickness of the electrodeposition layer (144b) on the surface of the insulation resin layer (141) was 7.4 μm and the peeling strength of the copper layer: 1.30 kg/cm on the side of the extra thin copper foil (143) and 0.65 kg/cm on the side of the insulation resin layer (141). Namely, the peeling strength of the copper layer on the side of the extra thin copper foil (143) was 0.9 kg/cm or more which was enough to stand against the packaging of parts, the electrodeposition layer (144c) on the inside wall surface of the hole (145) was formed in a thickness higher than the electrodeposition layer (144b) formed on the insulation resin layer (141) and the multilayer substrate had high reliability as to interlayer electrical connection in the hole (145).

### Example 11

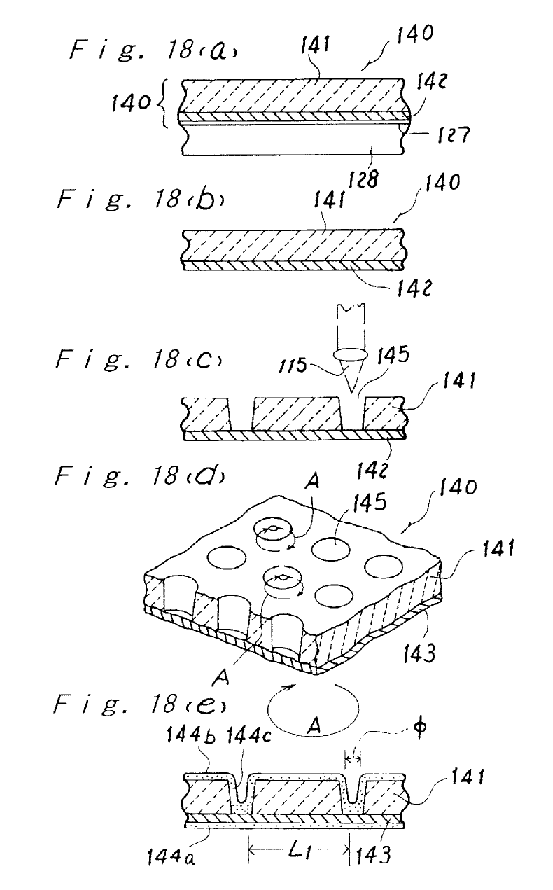

Example 11 of the present invention will be explained with reference to FIG. 19.

In Example 11, a glass cloth-containing resin is used as the insulation resin layer and a base material prepared by laminating an extra thin copper foil on one surface of the insulation resin layer by a hot press is provided with a hole reaching the extra thin copper foil and is processed by circular oscillation electroplating.

The base material provided with the extra thin copper foil on one surface of the insulation resin layer from which a carrier copper foil is peeled off is subjected to via-working using a UV-YAG laser from the side of the insulation resin layer to form a hole reaching the extra thin copper foil in the same manner as in the above Example 10. Then, the extra thin copper foil having a thickness of 5 μm is etched to form an extra thin copper foil 2.9 μm in thickness. Then, the base material is performed by desmearing treatment, electroless plating or activating treatment to make it possible to carry out electroplating on the base material. This base material is circularly oscillated in a copper plating bath to carry out circular oscillation electroplating.

FIG. 19 is a sectional view showing the multilayer substrate for a buildup with a via which has been subjected to circular oscillation electroplating. The insulation resin layer (151) is made of a glass cloth-containing epoxy resin equivalent to an FR4 and has a thickness of 60 μm. The extra thin copper foil (153) is made to have a thickness reduced to 2.9 μm from 5 μm by etching and the surface roughness of the extra thin copper foil on the side which is in contact with the insulation resin layer (151), namely, Rz is 2.4 (μm). Electrodeposition layers (154a) to (154d) are formed by circular oscillation electroplating.

This multilayer substrate for a buildup with a via had the following characteristics: interval L1 between the holes: 200 μm, diameter φ of the hole=60 μm, the thickness of the electrodeposition layer (154c) on the inside wall surface of the hole was 8.2 μm, the thickness of the electrodeposition layer (154a) on the surface of the extra thin copper foil (153) was 10.5 μm, the thickness of the electrodeposition layer (154b) on the surface of the insulation resin layer (151) was 7.4 μm and peeling strength of the copper layer: 1.24 kg/cm on the side of the extra thin copper foil (153) and 0.65 kg/cm on the side of the insulation resin layer (151). Namely, the peeling strength of the copper layer on the side of the extra thin copper foil (153) was 0.9 kg/cm or more which was enough to stand against the packaging of parts, the electrodeposition layer (154c) on the inside wall surface of the hole was formed in a thickness higher than the electrodeposition layer (144b) on the insulation resin layer (151) and the multilayer substrate had high reliability as to interlayer electrical connection.

Also, the use of the glass cloth-containing resin for the insulation resin layer (151) rendered the substrate free from deformations such as flexure or the occurrences of partial irregularities in the step of forming a hole by the laser via-working.

### Example 12

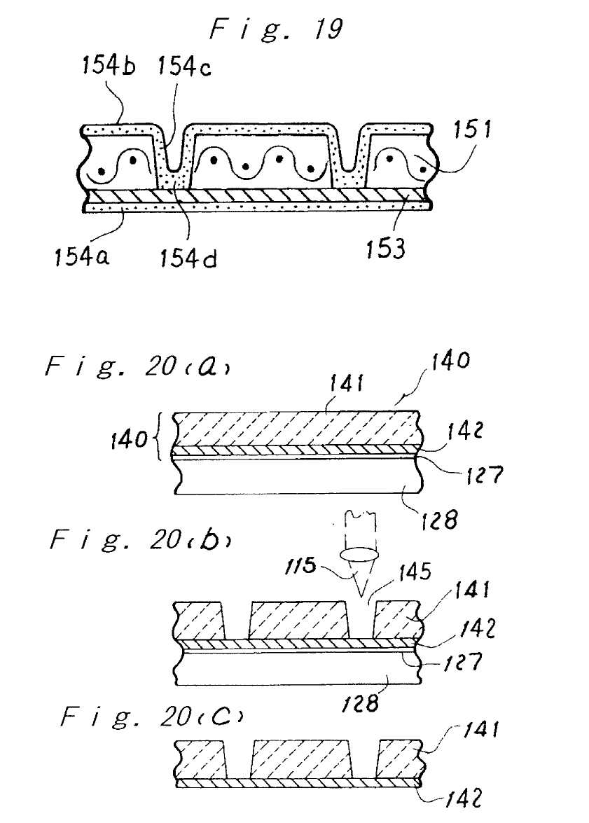

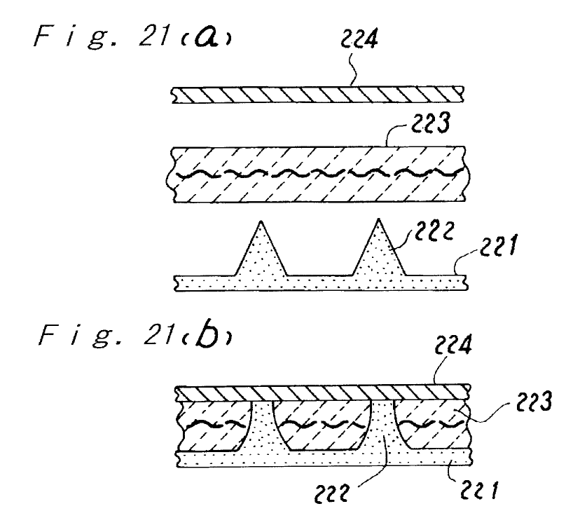

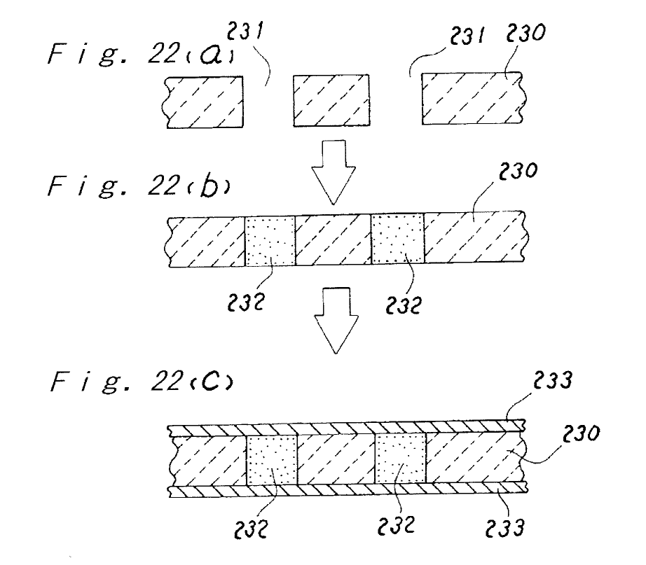

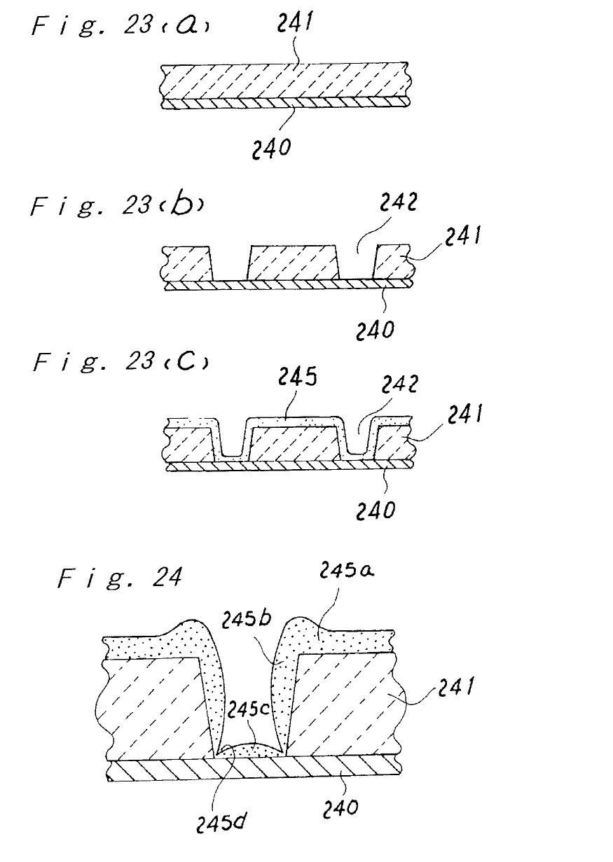

Example 12 of the present invention will be explained with reference to FIG. 20.

Example 12 shows a step of forming a hole reaching an extra thin copper foil on an insulation resin layer of a base material in the state of the base material bound with a carrier copper foil.

FIG. 20(a) to FIG. 20(c) are explanatory views showing the formation of a hole.

As shown by the sectional view in FIG. 20(a), a base material (140) is bound with a carrier copper foil (128). The base material (140) is prepared by laminating an extra thin copper foil (142) on one surface of an insulation resin layer (141) by a hot press. Also, the carrier copper foil (128) is treated with chromate (127) of about 0.01 μm in thickness as a peelable layer.

As shown by the sectional view in FIG. 20(b), a hole (145) reaching the extra thin copper foil (142) is formed by laser via-working using a UV-YAG laser (115) from the side of the insulation resin layer (142) of the base material in the state of the base material (140) bound with the carrier copper foil (128). The laser via-working performed from the side of the insulation resin layer (141) in the state of the base material (140) bound with the carrier copper foil (128) prevents the extra thin copper foil (142) from melting.

After the hole (145) is formed, the base material (140) is peeled off from the carrier copper foil (128) as shown by the sectional view in FIG. 20(c). In the same manner as in the above-mentioned Examples 10 and 11, the base material is subjected to desmearing treatment, electroless plating or activating treatment to enable copper electroplating. The base material is then oscillated circularly in a copper plating bath to carry out circular oscillation electroplating to form an electrodeposition layer in the hole (145), thereby producing a multilayer substrate for a buildup with a via.

An example of the arrangement of the hole provided with an electrodeposition layer in a substrate for a buildup with a via which is formed as in the above-mentioned Examples 7 to 12 will be given.

The substrate for a buildup (101) with a via as shown in FIG. 4 is provided with the through-hole (113) in which an electrodeposition layer is formed or the hole (145) reaching the extra thin copper foil in plural at specified intervals (X1) and (X2). This substrate is used as a universal substrate (multipurpose substrate). Among these holes (113) and (145) formed plurally, those disposed at the positions required to form a circuit are used to form the circuit when the circuit is formed on the substrate (101).

The substrate for a buildup (101) with a via as shown in FIG. 5 is provided with the through-holes (113) in which an electrodeposition layer is formed or with the holes (145) reaching the extra thin copper foil at only the positions required for forming a circuit and is therefore produced as a substrate for a specific circuit.

Having described our invention as related to the embodiment, it is our intention that the invention be not limited by any of the details of description, unless otherwise specified, but rather be constructed broadly within its spirit and scope as set out in the accompanying claims.

What is claimed is:

1. A multilayer substrate for a buildup with a via, which multilayer substrate comprises a base material comprising an insulation resin layer and, if necessary, a copper layer or an extra thin copper foil formed on either one or both surfaces of said insulation resin layer, and which multilayer substrate has a predetermined hole formed on said insulation resin layer,
wherein an electrodeposition layer is formed by circular oscillation electroplating on the inside wall surface of said hole and on the predetermined surface of said insulation resin layer,
the electrodeposition layer on said inside wall surface of said hole being formed in a thickness greater than the electrodeposition layer formed on said surface of said insulation resin layer.

2. The multilayer substrate for a buildup with a via according to claim 1, which multilayer substrate comprises the base material comprising the insulation resin layer and the copper layer formed on one surface thereof, and which multilayer substrate has the hole which reaches said copper layer formed on one surface and is formed on the insulation resin layer,
wherein the electrodeposition layer is formed by circular oscillation electroplating on the inside wall surface of said hole and on the surface of the copper-layer unformed-side of said insulation resin layer,
the electrodeposition layer on said inside wall surface of said hole being formed in a thickness greater than the electrodeposition layer formed on said surface of said insulation resin layer.

3. The multilayer substrate for a buildup with a via according to claim 2, wherein the hole on the insulation resin layer is filled up with the electrodeposition layer formed on the inside wall surface of said hole formed on the insulation resin layer.

4. The multilayer substrate for a buildup with a via according to claim 2, wherein the hole provided with the electrodeposition layer formed on the inside wall surface thereof on the insulation resin layer is plurally formed at predetermined intervals on the multilayer substrate.

5. The multilayer substrate for a buildup with a via according to claim 2, wherein the hole provided with the electrodeposition layer formed on the inside wall surface thereof in the insulation resin layer is plurally formed at circuit-formed positions on the multilayer substrate.

6. The multilayer substrate for a buildup with a via according to claim 1, which multilayer substrate comprises the base material on which the hole penetrating through the insulation resin layer is formed,
wherein the electrodeposition layer is formed by circular oscillation electroplating on the inside wall surface of said hole and on both surfaces of said insulation resin layer,
the electrodeposition layer on said inside wall surface of said hole being formed in a thickness greater than the electrodeposition layer formed on both surfaces of said insulation resin layer.

7. The multilayer substrate for a buildup with a via according to claim 6, wherein the hole on the insulation resin layer is filled up with the electrodeposition layer formed on inside wall surface of said hole on the insulation resin layer.

8. The multilayer substrate for a buildup with a via according to claim 6, wherein the hole provided with the electrodeposition layer formed on the inside wall surface thereof in the insulation resin layer is plurally formed at predetermined intervals on the multilayer substrate.

9. The multilayer substrate for a buildup with a via according to claim 6, wherein the hole provided with the electrodeposition layer formed on the inside wall surface thereof in the insulation resin layer is plurally formed at circuit-formed positions on the multilayer substrate.

10. The multilayer substrate for a buildup with a via according to claim 1, which multilayer substrate comprises a base material having an extra thin copper foil on one side of the insulation resin layer and a through-hole formed thereon,
wherein the electrodeposition layer is formed on the surface of said extra thin copper foil, on the surface of said insulation resin layer and on the inside wall surface of said through-hole by circular oscillation electroplating,
the electrodeposition layer on the inside wall surface of the through-hole being formed in a thickness larger than the electrodeposition layer on the surface of the insulation resin layer.

11. The multilayer substrate for a buildup with a via according to claim 10, wherein the through-hole is filled up with the electrodeposition layer formed on the inside wall surface of said through-hole.

12. The multilayer substrate for a buildup with a via according to claim 10, wherein the extra thin copper foil on one surface of the insulation resin layer has a thickness of 1 to 5 μm.

13. The multilayer substrate for a buildup with a via according to claim 1, which multilayer substrate comprises the base material having an extra thin copper foil on one surface of the insulation resin layer and which multilayer substrate has a hole reaching said extra thin copper foil and formed on the insulation resin layer,
wherein the electrodeposition layer is formed on the surface of the extra thin copper foil, on the surface of said insulation resin layer and on the inside wall surface of said hole by circular oscillation electroplating,
the electrodeposition layer on said inside wall surface of said hole being formed in a thickness larger than the electrodeposition layer on the surface of said insulation resin layer.

14. The multilayer substrate for a buildup with a via according to claim 13, wherein the hole is filled up with the electrodeposition layer formed on the inside wall surface of the hole reaching the extra thin copper foil in the insulation resin layer.

15. The multilayer substrate for a buildup with a via according to claim 13, wherein the extra thin copper foil on one surface of the insulation resin layer has a thickness of 1 to 5 μm.

16. A method for producing a multilayer substrate for a buildup with a via, comprising:
a step of forming a predetermined hole using a laser in a base material comprising an insulation resin layer and, if necessary, a copper layer or an extra thin copper foil formed on either one or both surfaces of said insulation resin layer;
a step of performing electroless plating, copper sputtering or activating treatment on the base material on which said hole is formed; and
an electroplating step of performing electroplating to generate a vortex flow of an electroplating solution inside said hole by oscillating said base material circularly in an electroplating bath, to form an electrodeposition layer on the inside wall surface of said hole and on a predetermined surface of said insulation resin layer, whereby the electrodeposition layer on the inside wall surface of said hole is formed in a thickness larger than the electrodeposition layer formed on said surface of said insulation resin layer.

17. The method for producing the multilayer substrate for a buildup with a via according to claim 16, comprising:
a step of forming the hole reaching the copper layer, formed on one surface, by using a laser on the insulation resin layer formed on the base material comprising said insulation resin layer and said copper layer formed on one surface;
a step of performing electroless plating, copper sputtering or activating treatment on the base material in which said hole is formed; and
an electroplating step of performing electroplating to generate the vortex flow of the electroplating solution inside of said hole by oscillating said base material circularly in the electroplating bath to form the electrodeposition layer on the inside wall surface of said hole and on the surface of the copper-layer unformed-side of said insulation resin layer, whereby the electrodeposition layer on said inside wall surface of said hole is formed in a thickness larger than the electrodeposition layer formed on said surface of the copper-layer unformed-side of said insulation resin layer.

18. The method for producing the multilayer substrate for a buildup with a via according to claim 17, wherein, in the electroplating step of generating the vortex flow inside the hole by oscillating circularly in the electroplating bath, the flow rate of the electroplating solution inside said hole is higher than that of the electroplating solution on the surface of the insulation resin layer.

19. The method for producing the multilayer substrate for a buildup with a via according to claim 16, comprising:
a step of forming a hole penetrating through an insulation resin layer by using a laser;
a step of performing electroless plating, copper sputtering or activating treatment on the base material in which said hole is formed; and
an electroplating step of performing electroplating to generate the vortex flow of an electroplating solution inside said hole by oscillating the base material circularly in the electroplating bath, to form the electrodeposition layer on the inside wall surface of said hole and on both surfaces of said insulation resin layer, whereby the electrodeposition layer on the inside wall surface of the said is formed in a thickness larger than the electrodeposition layer formed on both surfaces of said insulation resin layer.

20. The method for producing the multilayer substrate for a buildup with a via according to claim 19, wherein, in the electroplating step of generating the vortex flow inside the hole by the circular oscillation in the electroplating bath, the flow rate of the electroplating solution inside said hole is higher than that of the solution on the surface of the insulation resin layer.

21. The method of producing the multilayer substrate for a buildup with a via according to claim 16, comprising:
a step of working an extra thin copper foil of the base material having said extra thin copper foil on one surface of the insulation resin layer by treatment allowing good laser workability to form a through-hole from the side of said extra thin copper foil by laser via-working;
a step of performing electroless plating, copper sputtering or activating treatment on the base material on which the through-hole is formed; and
a circular oscillation electroplating step of performing electroplating to generate the vortex flow of the electroplating solution inside said through-hole by oscillating said base material circularly in the electroplating bath to thereby form the electrodeposition layer on the surface of the extra thin copper foil, on the surface of the insulation resin layer and on the inside wall surface of the through-hole in said base material,
wherein the electrodeposition layer on said inside wall surface of said through-hole is formed in a thickness larger than the electrodeposition layer formed on said surface of said insulation resin layer.

22. The method for producing a multilayer substrate for a buildup with a via according to claim 16, comprising:
a step of peeling off the base material from a carrier copper foil and forming a through-hole by laser via-working from the side of the extra thin copper foil treated for allowing good laser workability, wherein the base material having the extra thin copper foil treated for allowing good laser workability on one surface of the insulation resin layer is bonded with the carrier copper foil on said extra thin copper foil;
a step of performing electroless plating, copper sputtering or activating treatment on said base material on which the through-hole is formed; and
a circular oscillation electroplating step of performing electroplating to generate the vortex flow of the electroplating solution inside of the through-hole by oscillating said base material circularly in the electroplating bath to thereby form the electrodeposition layer on the surface of the extra thin copper foil, on the surface of the insulation resin layer and on the inside wall surface of the through-hole on said base material, wherein the electrodeposition layer on said inside wall surface of said through-hole is formed in a thickness larger than the electrodeposition layer formed on the surface of said insulation resin layer.

23. The method for producing the multilayer substrate for a buildup with a via according to claim 16, comprising:
a step of processing a copper foil of the base material having said copper foil on one surface of the insulation resin layer by treatment for allowing good laser workability and forming a through-hole from the side of said copper foil by laser via-working;
a step of making the copper foil of said base material, on which said through-hole is formed, into an extra thin copper foil by etching;
a step of performing electroless plating, copper sputtering or activating treatment on said base material; and
a circular oscillation electroplating step of performing electroplating to generate the vortex flow of the electroplating solution inside the through-hole by oscillating said base material circularly in an electroplating bath to thereby form the electrodeposition layer on the surface of the extra thin copper foil, on the surface of the insulation resin layer and on the inside wall surface of said through-hole in said base material, wherein the electrodeposition layer on said inside wall surface of said through-hole is formed in a thickness larger than the electrodeposition layer formed on said surface of the insulation resin layer.

24. The method for producing the multilayer substrate for a buildup with a via according to claim 16, comprising:
a step of forming the hole reaching the extra thin copper foil on the insulation resin layer by performing laser via-working from the side of the insulation resin layer of the base material having the extra thin copper foil on one surface of the insulation resin layer;
a step of performing electroless plating, copper sputtering or activating treatment on said base material on which said hole reaching said extra thin copper foil is formed on said insulation resin layer; and
a circular oscillation electroplating step of performing electroplating to generate the vortex flow of the electroplating solution inside said hole of said insulation resin layer reaching said extra thin copper foil by oscillating said base material circularly in the electroplating bath to thereby form the electrodeposition layer on the surface of the extra thin copper foil, on the surface of the insulation resin layer and on the inside wall surface of the hole in the base material,
wherein the electrodeposition layer on the inside wall surface of said hole is formed in a thickness larger than the electrodeposition layer formed on said surface of said insulation resin layer.

25. The method for producing the multilayer substrate for a buildup with a via according to claim 16, comprising:
a step of forming the hole reaching the extra thin copper foil on the insulation resin layer by performing laser via-working from the side of the insulation resin layer of the base material in the condition that the base material is bonded with the carrier copper foil, wherein the base material provided with the extra thin copper foil on one surface of the insulation resin layer is bonded with a carrier copper foil;
a step of peeling off said base material provided with said hole reaching said extra thin copper foil which hole is formed on the insulation resin layer, from said carrier copper foil and performing electroless plating, copper sputtering or activating treatment on the base material in which the through-hole is formed; and
a circular oscillation electroplating step of performing electroplating to generate the vortex flow of the electroplating solution inside said hole of said insulation resin layer reaching said extra thin copper foil by oscillating said base material circularly in the electroplating bath to thereby form the electrodeposition layer on the surface of the extra thin copper foil, on the surface of said insulation resin layer and on said inside wall surface of said hole in the base material,
wherein the electrodeposition layer on said inside wall surface of said hole is formed in a thickness larger than the electrodeposition layer formed on the surface of said insulation resin layer.
